(19) United States
(12) Patent Application Publication
(10) Pub. No.: US 2026/0188209 A1
(43) Pub. Date: Jul. 2, 2026

(54) Pixel Circuit, Driving Method Therefor, Display Substrate and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Zhu WANG, Beijing (CN); Ling SHI, Beijing (CN); Zhongman ZHAO, Beijing (CN); Yanyang SHANG, Beijing (CN); Zhenglong YAN, Beijing (CN)

(21) Appl. No.: 18/839,442

(22) PCT Filed: Oct. 30, 2023
(86) PCT No.: PCT/CN2023/127829

§ 371 Date: Aug. 19, 2024

(51) Int. Cl. G09G 3/3233

(52) U.S. Cl. CPC G09G 3/3233; G09G 2300/0426; G09G 2300/0852; G09G 2300/0861; G09G 2310/08; G09G 2320/0233; G09G 2340/0435

(57) ABSTRACT

A pixel circuit includes a driving sub-circuit, a first voltage writing sub-circuit, a second voltage writing sub-circuit, a writing control sub-circuit, a coupling sub-circuit, a first reset sub-circuit, and a storage sub-circuit. The first voltage writing sub-circuit is configured to write a data signal provided by the data line (DL) to a third node (N3) under the control of a first scan line (GL1) in a data writing stage. The second voltage writing sub-circuit is configured to write a threshold voltage of the driving sub-circuit to the third node (N3) under the control of a compensation control line (GP) in a threshold compensation stage. The writing control sub-circuit is configured to conduct the third node (N3) and a fourth node (N3). The coupling sub-circuit is configured to couple a signal written to the fourth node (N4) to the first node (N1).

### CROSS-REFERENCE TO RELATED APPLICATION

The present application is a U.S. National Phase Entry of International Application No. PCT/CN2023/127829 having an international filing date of Oct. 30, 2023, the entire content of which is hereby incorporated by reference.

### TECHNICAL FIELD

The present document relates to, but is not limited to, display technologies, in particular to a pixel circuit, a method for driving the pixel circuit, a display substrate, and a display apparatus.

### BACKGROUND

An Organic Light Emitting Diode (OLED) with advantages of ultra-thin design, large field of view, active emission, high brightness, continuous and adjustable light colors, low cost, quick response, low power consumption, wide working temperature range, flexible display, and the like, has gradually become a next-generation display technology with a broad development prospect and attracted more and more attention. The OLED may be divided into a Passive Matrix (PM) type and an Active Matrix (AM) type according to different drive modes. An AMOLED is a current-driven device and controls each sub-pixel using an independent Thin Film Transistor (TFT), and each sub-pixel may be continuously and independently driven to emit light.

In recent years, with the rapid development of display industry, AMOLED display screens are used in various industries, such as mobile phones, bracelets, watches, car displays, laptop computers, televisions and so on. However, with the continuous development of industries having high requirements on refresh rate, such as real-time games, consumers have higher and higher requirements on display screens, and display screens with high refresh or even ultra-high refresh are gradually needed by various industries.

### SUMMARY

The following is a summary of subject matters described herein in detail. This summary is not intended to limit the protection scope of claims.

Embodiments of the present disclosure provide a pixel circuit, a method for driving the pixel circuit, a display substrate, and a display apparatus.

In one aspect, the present embodiment provides a pixel circuit including a driving sub-circuit, a first voltage writing sub-circuit, a second voltage writing sub-circuit, a writing control sub-circuit, a coupling sub-circuit, a first reset sub-circuit, and a storage sub-circuit. The driving sub-circuit is coupled to a first node, a second node and a third node, and is configured to provide a driving signal to the third node under control of the first node. The first reset sub-circuit is coupled to the first node, a first reset control line and a first initial signal line, and is configured to write a first initial signal provided by the first initial signal line to the first node under control of the first reset control line. The first voltage writing sub-circuit is coupled to the third node, a first scan line and a data line, and is configured to write a data signal provided by the data line to the third node under control of the first scan line in a data writing stage. The second voltage writing sub-circuit is coupled to the second node, a compensation control line and a second initial signal line, and is configured to write a threshold voltage of the driving sub-circuit to the third node under control of the compensation control line in a threshold compensation stage. The writing control sub-circuit is coupled to the third node, a fourth node and a second scan line, and is configured to conduct the third node and the fourth node under control of the second scan line in the data writing stage and the threshold compensation stage. The coupling sub-circuit is coupled to the first node and the fourth node, and is configured to couple a signal written to the fourth node to the first node. The storage sub-circuit is coupled to the first node and a first power supply line. In one display period, the threshold compensation stage is independent of the data writing stage.

In some exemplary implementations, in one display period, the threshold compensation stage is before the data writing stage, and a time length of the threshold compensation stage is greater than a time length of the data writing stage.

In some exemplary implementations, the pixel circuit further includes a first control sub-circuit and a second control sub-circuit. The first control sub-circuit is coupled to the second node, the first control line and the first power supply line, and is configured to conduct the first power supply line and the second node under control of the first control line. The second control sub-circuit coupled to the third node, the second control line and the fifth node, and is configured to transmit the drive signal to the fifth node under control of the second control line; and the fifth node is coupled to a first electrode of a light emitting element, and a second electrode of the light emitting element is coupled to a second power supply line.

In some exemplary implementations, a first control signal provided by the first control line is different from a second control signal provided by the second control line.

In some exemplary implementations, the pixel circuit further includes a third voltage writing sub-circuit, which is coupled to the third node, a third scan line, and a fourth initial signal line and configured to write a fourth initial signal provided by the fourth initial signal line to the third node under control of the third scan line before the threshold compensation stage.

In some exemplary implementations, the first initial signal provided by the first initial signal line is the same as a second initial signal provided by the second initial signal line, and the fourth initial signal provided by the fourth initial signal line is greater than the first initial signal provided by the first initial signal line.

In some exemplary implementations, a first control signal provided by the first control line is the same as a second control signal provided by the second control line.

In some exemplary implementations, the pixel circuit further includes a second reset sub-circuit, which is coupled to the fifth node, a second reset control line and a third initial signal line and is configured to write a third initial signal provided by the third initial signal line to the fifth node under control of the second reset control line.

In some exemplary implementations, the first reset sub-circuit includes a first transistor. A gate electrode of the first transistor is coupled to the first reset control line, a first electrode of the first transistor is coupled to the first initial signal line, and a second electrode of the first transistor is coupled to the first node. The writing control sub-circuit includes a second transistor, a gate electrode of the second transistor is coupled to the second scan line, a first electrode of the second transistor is coupled to the third node, and a second electrode of the second transistor is coupled to the fourth node. The driving sub-circuit includes a third transistor, a gate electrode of the third transistor is coupled to the first node, a first electrode of the third transistor is coupled to the second node, and a second electrode of the third transistor is coupled to the third node. The first voltage writing sub-circuit includes a fourth transistor, a gate electrode of the fourth transistor is coupled to the first scan line, a first electrode of the fourth transistor is coupled to the data line, and a second electrode of the fourth transistor is coupled to the third node. The second voltage writing sub-circuit includes a seventh transistor, a gate electrode of the seventh transistor is coupled to the compensation control line, a first electrode of the seventh transistor is coupled to the second initial signal line, and a second electrode of the seventh transistor is coupled to the second node. The first control sub-circuit includes a fifth transistor, a gate electrode of the fifth transistor is coupled to the first control line, a first electrode of the fifth transistor is coupled to the first power supply line, and a second electrode of the fifth transistor is coupled to the second node. The second control sub-circuit includes a sixth transistor, a gate electrode of the sixth transistor is coupled to the second control line, a first electrode of the sixth transistor is coupled to the third node, and a second electrode of the sixth transistor is coupled to the fifth node. The second reset sub-circuit includes an eighth transistor, a gate electrode of the eighth transistor is coupled to the second reset control line, a first electrode of the eighth transistor is coupled to the third initial signal line, and a second electrode of the eighth transistor is coupled to the fifth node. Herein, the third transistor, the fourth transistor, the fifth transistor, the sixth transistor, the seventh transistor, and the eighth transistor are a first type of transistors; the first transistor and the second transistor are a second type of transistors; and a transistor type of the first type of transistors and a transistor type of the second type of transistors are different.

In some exemplary implementations, the first type of transistors are low temperature polysilicon thin film transistors, and the second type of transistors are oxide thin film transistors.

In some exemplary implementations, the storage sub-circuit includes: a first capacitor; the coupling sub-circuit includes: a second capacitor; a first electrode of the first capacitor is coupled to the first node, and a second electrode of the first capacitor is coupled to the first power supply line; and a first electrode of the second capacitor is coupled to the fourth node, and a second electrode of the second capacitor is coupled to the first node.

On the other hand, the present embodiment provides a method for driving a pixel circuit, which is applied to the pixel circuit as described above, and includes that: a first reset sub-circuit writes a first initial signal provided by a first initial signal line to a first node under control of a first reset control line; in a threshold compensation stage, a second voltage writing sub-circuit writes a threshold voltage of a driving sub-circuit to a third node under control of a compensation control line, and a writing control circuit conducts the third node and a fourth node and writes the threshold voltage to the fourth node under control of a second scan line; in a data writing stage, a first voltage writing sub-circuit writes a data signal provided by a data line to a third node under control of a first scan line, the writing control circuit writes the data signal to the fourth node, and a coupling sub-circuit couples the signal written to the fourth node to the first node; and the driving sub-circuit provides a driving signal to the third node under control of the first node.

In some exemplary implementations, in one display period, the threshold compensation stage is before the data writing stage, and a time length of the threshold compensation stage is greater than a time length of the data writing stage.

In some exemplary implementations, the method for driving in the present example further includes that the first control sub-circuit charges the fourth node with a first voltage signal provided by the first power supply line under control of the first control line before the threshold compensation stage.

In some exemplary implementations, the pixel circuit further includes a third voltage writing sub-circuit, which is coupled to the third node, a third scan line, and a fourth initial signal line; and the method for driving further includes that: before the threshold compensation stage, the third voltage writing sub-circuit charges the fourth node using a fourth initial signal provided by the fourth initial signal line under control of the third scan line, the fourth initial signal is greater than the first initial signal.

In some exemplary implementations, in one display period, a duration of an effective level signal of a second scan signal provided by the second scan line is greater than a sum of a duration of an effective level signal of a first scan signal provided by the first scan line, a duration of an effective level signal of a third scan signal provided by the third scan line, and a duration of an effective level signal of a compensation control signal provided by the compensation control line.

On the other hand, the present embodiment provides a display substrate, including: a base substrate, and a circuit structure layer disposed on the base substrate. The circuit structure layer includes a plurality of pixel circuits, and at least one pixel circuit includes: a first capacitor and a second capacitor; and the second capacitor is located on a side of the first capacitor away from the base substrate, and an orthographic projection of the second capacitor on the base substrate is at least partially overlapped with an orthographic projection of the first capacitor on the base substrate. The first capacitor includes: a first electrode plate and a second electrode plate; and the second capacitor includes a third electrode plate and a fourth electrode plate. The second electrode plate of the first capacitor is located on a side of the first electrode plate away from the base substrate, the third electrode plate of the second capacitor is located on a side of the fourth electrode plate away from the base substrate, and the fourth electrode plate of the second capacitor is located on a side of the second electrode plate of the first capacitor away from the base substrate; and the first electrode plate of the first capacitor is connected to the fourth electrode plate of the second capacitor.

In some exemplary implementations, the second electrode plate of the first capacitor has a hollow region, and an orthographic projection of a connection position between the first electrode plate and the fourth electrode plate on the base substrate is located within a range of an orthographic projection of the hollow region on the base substrate.

In some exemplary implementations, an orthographic projection of the third electrode plate of the second capacitor on the base substrate covers orthographic projections of the first electrode plate and the fourth electrode plate on the base substrate.

In some exemplary implementations, second electrode plates of first capacitors of the plurality of pixel circuits disposed along a first direction are of an integral structure connected to each other, the integral structure is connected with a first power supply line extending along a second direction to form a mesh structure for transmitting a first voltage signal, and the first power supply line is located on a side of the integral structure away from the base substrate; and the first direction intersects with the second direction.

In some exemplary implementations, the integral structure formed by connecting the second electrode plates of the first capacitors of the plurality of pixel circuits disposed along the first direction is connected to the first power supply line through a ninth connection electrode, and the ninth connection electrode is located on a side of the integral structure away from the base substrate and located on a side of the first power supply line close to the base substrate.

In some exemplary implementations, the pixel circuit is connected to a first initial signal line, a second initial signal line, and a third initial signal line; and the first initial signal line, the second initial signal line, and the third initial signal line are located in different conductive layers.

In some exemplary implementations, the pixel circuit includes at least one first type of transistor, at least one second type of transistor. In a direction perpendicular to the display substrate, the circuit structure layer comprises: a first semiconductor layer, a first conductive layer, a second conductive layer, a second semiconductor layer, a third conductive layer, a fourth conductive layer, and a fifth conductive layer disposed on the base substrate, herein the first semiconductor layer comprises an active layer of the at least one first type of transistor, and the second semiconductor layer comprises an active layer of the at least one second type of transistor.

In some exemplary implementations, the first electrode plate of the first capacitor is located in the first conductive layer, and the second electrode plate of the first capacitor is located in the second conductive layer; and the third electrode plate of the second capacitor is located in the fifth conductive layer, and the fourth electrode plate of the second capacitor is located in the fourth conductive layer.

In some exemplary implementations, the pixel circuit is electrically connected to the first initial signal line which is located in the fourth conductive layer, and an orthographic projection of the first initial signal line on the base substrate is at least partially overlapped with orthographic projections of traces located in the second conductive layer and the third conductive layer on the base substrate.

In some exemplary implementations, the pixel circuit is electrically connected to a second initial signal line and a third initial signal line, the third initial signal line is located in the second conductive layer, the second initial signal line is located in the third conductive layer, and an orthographic projection of the second initial signal line on the base substrate is at least partially overlapped with an orthographic projection of the third initial signal line on the base substrate.

In some exemplary implementations, the pixel circuit includes two second type of transistors, which are adjacent in the first direction and are arranged in a staggered manner along the first direction.

In some exemplary implementations, the plurality of pixel circuits are divided into a plurality of pixel circuit groups, each of which includes two pixel circuits disposed to be adjacent along the first direction, and the two pixel circuits in the pixel circuit group are disposed symmetrically with respect to a first centerline of the pixel circuit group in the first direction.

In some exemplary implementations, two pixel circuits in the group of pixel circuits are connected to a same first power supply line, the first power supply line is located on the first centerline, and data lines to which the two pixel circuits are connected are located on two sides of the first power supply line in the first direction.

In another aspect, an embodiment of the present disclosure provides a display apparatus, which includes the aforementioned display substrate.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a portion of the specification, and are used for explaining the technical solutions of the present disclosure together with embodiments of the present disclosure, but do not constitute limitations on the technical solutions of the present disclosure.

FIG. 1 is a schematic diagram of a structure of a pixel circuit according to at least one embodiment of the present disclosure.

FIG. 2 is a schematic diagram of another structure of a pixel circuit according to at least one embodiment of the present disclosure.

FIG. 3 is a schematic diagram of another structure of a pixel circuit according to at least one embodiment of the present disclosure.

FIG. 4 is an equivalent circuit diagram of a pixel circuit according to at least one embodiment of the present disclosure.

FIGS. 5A and 5B are working timing diagrams of the pixel circuit shown in FIG. 4.

FIG. 6 is a schematic diagram of another structure of a pixel circuit according to at least one embodiment of the present disclosure.

FIG. 7 is another equivalent circuit diagram of a pixel circuit according to at least one embodiment of the present disclosure.

FIGS. 8A and 8B are working timing diagrams of the pixel circuit shown in FIG. 7.

FIG. 9 is a flowchart of a method for driving a pixel circuit according to at least one embodiment of the present disclosure.

FIG. 10 is a schematic diagram of a partial plan structure of a circuit structure layer of a display substrate according to at least one embodiment of the present disclosure.

FIG. 11 illustrates schematically a cross-sectional view of a part taken along a direction Q-Q′ in FIG. 10.

FIG. 12 is a schematic diagram of the display substrate after a first semiconductor layer is formed in FIG. 10.

FIG. 13A is a schematic diagram of the display substrate after a first conductive layer is formed in FIG. 10.

FIG. 13B is a schematic diagram of the first conductive layer in FIG. 13A.

FIG. 14A is a schematic diagram of the display substrate after a second conductive layer is formed in FIG. 10.

FIG. 14B is a schematic diagram of the second conductive layer in FIG. 14A.

FIG. 15A is a schematic diagram of a display substrate after a second semiconductor layer is formed in FIG. 10.

FIG. 15B is a schematic diagram of the second semiconductor layer in FIG. 15A.

FIG. 16A is a schematic diagram of the display substrate after a third conductive layer is formed in FIG. 10.

FIG. 16B is a schematic diagram of the third conductive layer in FIG. 16A.

FIG. 17 is a schematic diagram of a display substrate after a fifth insulation layer is formed in FIG. 10.

FIG. 18A is a schematic diagram of a display substrate after a fourth conductive layer is formed in FIG. 10.

FIG. 18B is a schematic diagram of the fourth conductive layer in FIG. 18A.

FIG. 19 is a schematic diagram of a display substrate after a sixth insulation layer is formed in FIG. 10.

FIG. 20 is a schematic diagram of a fifth conductive layer in FIG. 10.

FIG. 21 is a schematic diagram of a display apparatus according to at least one embodiment of the present disclosure.

### DETAILED DESCRIPTION

The embodiments of the present disclosure will be described below with reference to the drawings in detail. Implementation modes may be implemented in a plurality of different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between composition elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements with reference to the accompanying drawings, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to directions of the constituent elements described. Therefore, appropriate replacements based on situations are allowed, which is not limited to the expressions in the specification.

In the specification, unless otherwise specified and defined explicitly, terms “mount”, “mutually connect”, “connect”, and “couple” should be understood in a broad sense. For example, it may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations. Among them, an “electrical connection” includes a case where constituent elements are connected together through an element with a certain electrical effect. The “element with a certain electrical effect” is not particularly limited as long as electrical signals between the connected constituent elements may be transmitted. Examples of the “element with the certain electrical effect” not only include electrodes and wirings, but also include switching elements such as transistors, resistors, inductors, capacitors, other elements with one or more functions, etc.

In the specification, a transistor refers to an element which at least includes three terminals, i.e., a gate electrode, a drain electrode, and a source electrode. The transistor has a channel region between the drain electrode (drain electrode terminal, drain electrode region, or drain electrode) and the source electrode (source electrode terminal, source electrode region, or source electrode), and a current can flow through the drain electrode, the channel region, and the source electrode. In the specification, the channel region refers to a region through which a current mainly flows.

In the specification, to distinguish two electrodes of a transistor except a gate, one of the electrodes is referred to as a first electrode and the other electrode is referred to as a second electrode. The first electrode may be a source or a drain, and the second electrode may be a drain or a source. In a case that transistors with opposite polarities are used, or in a case that a direction of a current is changed during operation of a circuit, or the like, functions of the “source electrode” and the “drain electrode” are sometimes interchangeable. Therefore, the “source electrode” and the “drain electrode” are interchangeable in the specification.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 800 and below 100°, and thus may include a state in which the angle is above 850 and below 95°.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, and deformation, etc.

In the present disclosure, “about” and “substantially” refer to that a boundary is not defined strictly and a case within a range of process and measurement errors is allowed. In the present disclosure, “same” includes completely the same or substantially the same, herein “substantially the same” refers to a case where a numerical value differs by less than 10%.

In the present disclosure, “A extends along a B direction” means that A may include a main body portion and a secondary portion connected with the main body portion, the main body portion is a line, a line segment, or a strip-shaped body, the main body portion extends along the B direction, and a length of the main body portion extending along the B direction is greater than a length of the secondary portion extending along another direction. In following description, “A extends along a B direction” means “a main body portion of A extends along a B direction”.

In the present disclosure, an effective level signal includes a level signal for turning on a transistor, for example, an effective level signal for turning on a P-type transistor is a low level signal, and an effective level signal for turning on an N-type transistor is a high level signal.

In some implementations, for a high-frequency driving application range (such as display scenarios greater than 120 Hz, for example, high-frequency (such as 240 Hz or 360 Hz) display scenarios), the data writing time length and the threshold voltage compensation time length of the display substrate are severely compressed, which results in insufficient compensation time length of the threshold voltage, thus making a sensitivity and a compensation effect of the threshold voltage poor, and affecting a display effect.

An embodiment provides a pixel circuit and a method for driving the pixel circuit, a display substrate and a display apparatus, which may improve a situation of insufficient compensation time length of the threshold voltage at a high-frequency driving, thereby improving a high-frequency display performance.

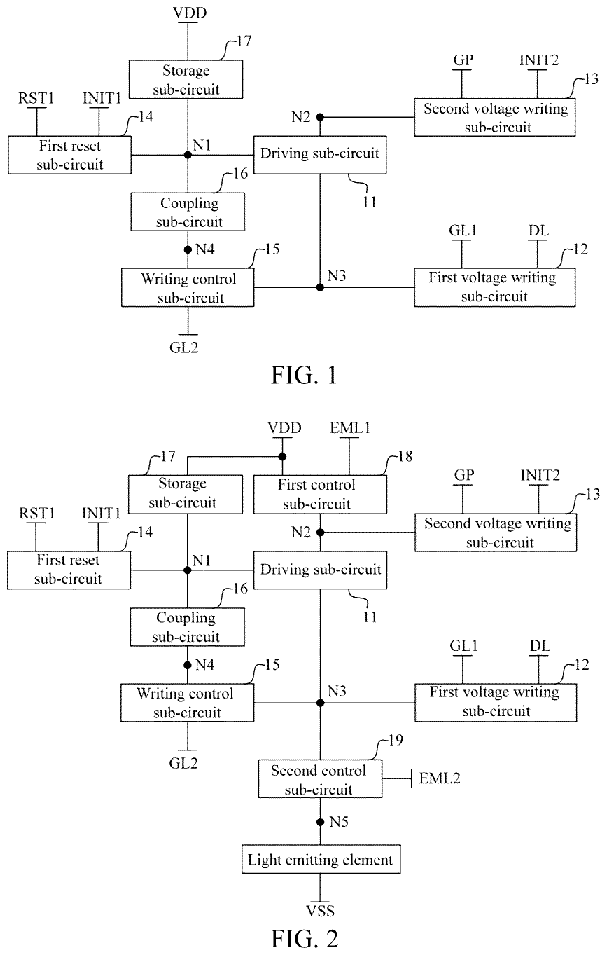

FIG. 1 is a schematic diagram of a structure of a pixel circuit according to at least one embodiment of the present disclosure. In some examples, as shown in FIG. 1, the pixel circuit of the present embodiment may include a driving sub-circuit 11, a first voltage writing sub-circuit 12, a second voltage writing sub-circuit 13, a first reset sub-circuit 14, a writing control sub-circuit 15, a coupling sub-circuit 16, and a storage sub-circuit 17. The driving sub-circuit is coupled with a first node N1, a second node N2, and a third node N3, and is configured to provide a driving signal to the third node N3 under the control of the first node N1. The first reset sub-circuit 14 is coupled to the first node N1, a first reset control line RST1, and a first initial signal line INIT1, and is configured to write a first initial signal provided by the first initial signal line INIT1 to the first node N1 under the control of the first reset control line RST1. The first voltage writing sub-circuit 12 is coupled to the third node N3, a first scan line GL1, and a data line DL, and is configured to write a data signal provided by the data line DL to the third node N3 under the control of the first scan line GL1 in a data writing stage. The second voltage writing sub-circuit 13 is coupled to the second node N2, a compensation control line GP, and a second initial signal line INIT2, and is configured to write a threshold voltage of the driving sub-circuit 11 to the third node N3 under the control of the compensation control line GP in a threshold compensation stage. The writing control sub-circuit 15 is coupled to the third node N3, a fourth node N4, and a second scan line GL2, and is configured to conduct the third node N3 and the fourth node N4 under the control of the second scan line GL2 in the data writing stage and the threshold compensation stage. The coupling sub-circuit 16 is coupled to the first node N1 and the fourth node N4 and is configured to couple a signal written to the fourth node N4 to the first node N1. The storage sub-circuit 17 is coupled to the first node N1 and a first power supply line VDD, and is configured to store a voltage of the first node N1. In one display period, the threshold compensation stage is independent of the data writing stage.

According to the pixel circuit provided by the present embodiment, the data signal and the threshold voltage of the driving sub-circuit may be written to the fourth node through the third node and the writing control sub-circuit at different stages, and then written to the first node through the coupling sub-circuit. The writing processes of the data signal and the threshold voltage are controlled separately, which may be beneficial to flexibly adjusting the writing compensation time length of the threshold voltage as needed, thereby increasing the compensation time length of the threshold voltage, making the compensation time length of the threshold voltage sufficient, thereby reducing the severity of poor display caused by insufficient compensation for the threshold voltage, and improving the yield rate of the display substrate. Moreover, the writing processes of the data signal and the threshold voltage are controlled separately, which may reduce the writing time length of the data signal on the basis of ensuring the compensation time length of the threshold voltage. The compensation for the threshold voltage is not affected by the writing process of the data signal, and the complete compensation for the threshold voltage may be achieved at a high refresh rate, which thus is beneficial to supporting a display product with a high refresh rate and improving display brightness, and improving display uniformity.

In some examples, in one display period, the threshold compensation stage is before the data writing stage, and a time length of the threshold compensation stage may be greater than a time length of the data writing stage. In some examples, the first scan line GL1 provides a first scan signal, and the compensation control line GP provides a compensation control signal. In one display period, a duration of an effective level signal of the first scan signal (e.g., a low-level signal) may be greater than a duration of an effective level signal of the compensation control signal, and an end time of an effective level signal of the compensation control signal may be earlier than a start time of an effective level signal of the first scan signal. The first scan signal and the compensation control signal may be provided by different gate drive circuits. In some examples, a time length of the compensation control signal may be adjusted in different display period. In this example, the compensation control signal may be used to control the compensation time length of the threshold voltage, which may be beneficial to achieving sufficient compensation for the threshold voltage, thereby reducing the poor display caused by insufficient compensation for the threshold voltage.

In some examples, the second scan line GL2 may provide a second scan signal, and the first reset control line RST1 may provide a first reset control signal. In one display period, a duration of an effective level signal of the first reset control signal (e.g., a high level signal) may be the same as a duration of an effective level signal of the second scan signal. A start time of an effective level signal of the first reset control signal may be earlier than a start time of the effective level signal of the second scan signal, and an end time of an effective level signal of the first reset control signal may be later than a start time of an effective level signal of the second scan signal. The first reset control signal and the second scan signal may be provided by different stages of shift register units in the same gate drive circuit, for example, an n-th stage shift register unit in one gate drive circuit may provide a first reset control signal, and an (n+7)-th stage shift register unit in the gate drive circuit may provide the second scan signal, and n may be an integer greater than 0.

In some examples, the first initial signal provided by the first initial signal line INIT1 may be the same as the second initial signal provided by the second initial signal line INIT2. In the present example, the voltage written to the first node may be independent of the second initial signal, and only the data signal and the threshold voltage are written to the first node. In other examples, the second initial signal may be smaller than the first initial signal.

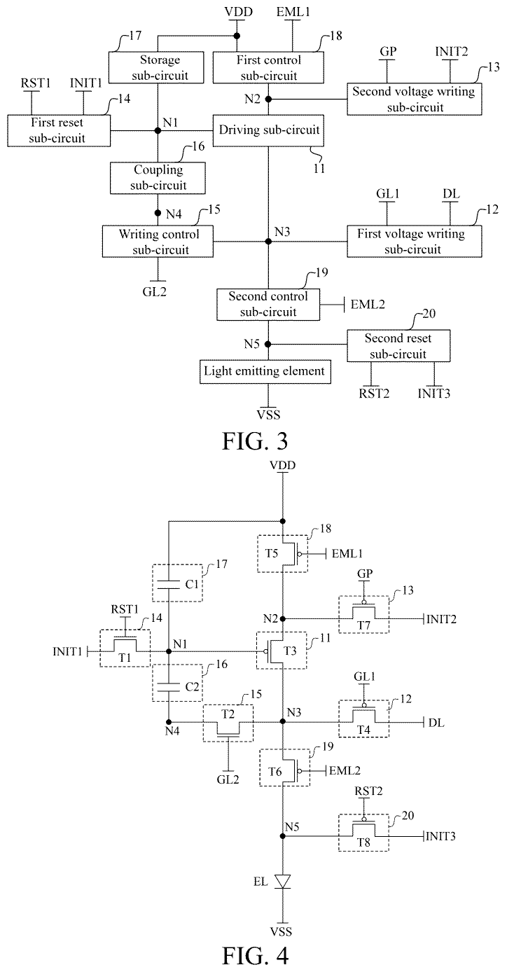

FIG. 2 is a schematic diagram of another structure of a pixel circuit according to at least one embodiment of the present disclosure. In some examples, as shown in FIG. 2, the pixel circuit of the present embodiment may include a driving sub-circuit 11, a first voltage writing sub-circuit 12, a second voltage writing sub-circuit 13, a first reset sub-circuit 14, a writing control sub-circuit 15, a coupling sub-circuit 16, a storage sub-circuit 17, a first control sub-circuit 18, and a second control sub-circuit 19. The first control sub-circuit 18 is coupled to the second node N2, a first control line EML1, and a first power supply line VDD, and is configured to conduct the first power supply line VDD and the second node N2 under the control of the first control line EML1. The second control sub-circuit 19 is coupled to the third node N3, the fifth node N5, and the second control line EML2, and is configured to transmit a drive signal to the fifth node N5 under the control of the second control line EML2. The fifth node N5 is coupled to a first electrode of the light emitting element, and the second electrode of the light emitting element may be coupled to the second power supply line VSS. Rest of the structure of the pixel circuit according to this example may refer to descriptions of the aforementioned embodiments, and thus will not be repeated here.

In some examples, the light emitting element may be an organic light emitting diode (OLED). The first electrode of the light emitting element may be an anode and the second electrode of the light emitting element may be a cathode. However, the present embodiment is not limited thereto.

In some examples, the first power supply line VDD may provide a constant high-level signal continuously, for example, the first power supply line may provide a first voltage signal. A second power supply line VSS may provide a constant low-level signal continuously, for example, the second power supply line VSS may provide a second voltage signal. The first voltage signal may be greater than the second voltage signal.

In some examples, a first control signal provided by the first control line EML1 may be different from a second control signal provided by the second control line EML2. For example, in one display period, a duration of an effective level signal of the first control signal (e.g., a low level signal) may be greater than a duration of an effective level signal of the second control signal, and an end time of the effective level signal of the first control signal may be later than an end time of the effective level signal of the second control signal. A start time of the effective level signal of the first control signal may be the same as a start time of the effective level signal of the second control signal. The first control signal and the second control signal may be generated by different gate drive circuits. For example, before the threshold compensation stage, the first control signal provided by the first control line EML1 may control the first power supply line VDD and the second node N2 to be conducted to charge the fourth node N4 with the first voltage signal provided by the first power supply line VDD, while at this time the second control signal provided by the second control line EML2 may control the third node N3 and the fifth node N5 to be disconnected.

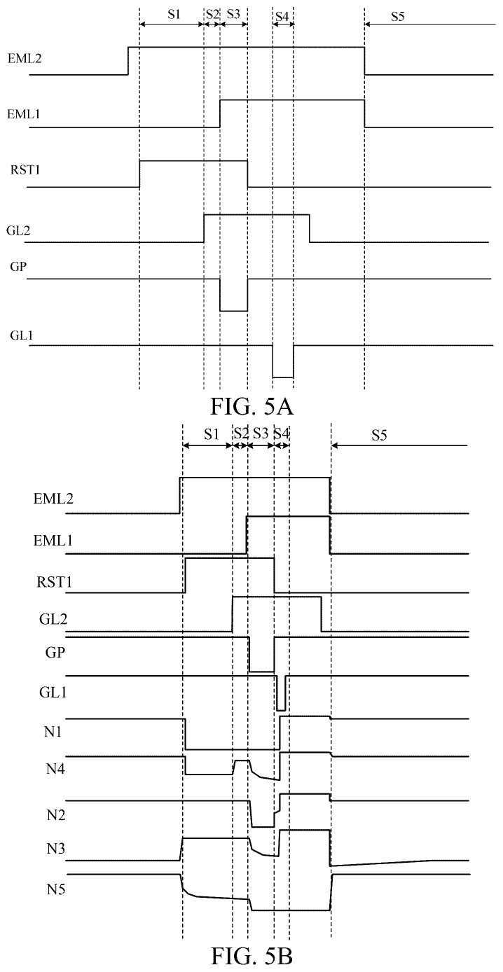

FIG. 3 is a schematic diagram of another structure of a pixel circuit according to at least one embodiment of the present disclosure. In some examples, as shown in FIG. 3, the pixel circuit of the present embodiment may include a driving sub-circuit 11, a first voltage writing sub-circuit 12, a second voltage writing sub-circuit 13, a first reset sub-circuit 14, a writing control sub-circuit 15, a coupling sub-circuit 16, a storage sub-circuit 17, a first control sub-circuit 18, a second control sub-circuit 19, and a second reset sub-circuit 20. The second reset sub-circuit 20 is coupled to the fifth node N5, the second reset control line RST2, and the third initial signal line INIT3, and is configured to write a third initial signal provided by the third initial signal line INIT3 to the fifth node N5 under the control of the second reset control line RST2. Rest of the structure of the pixel circuit according to this example may refer to descriptions of the aforementioned embodiments, and thus will not be repeated here.

In some examples, the third initial signal provided by the third initial signal line INIT3 may be different from the first initial signal provided by the first initial signal line INIT1. However, the present embodiment is not limited thereto. In this example, the fifth node N5 is initialized by providing the second reset sub-circuit 20.

In some examples, the compensation control signal provided by the compensation control line GP may be the same as the second reset control signal provided by the second reset control line RST2. In some examples, the compensation control signal and the second reset control signal may be generated by the same gate drive circuit, for example, by a same stage shift register unit in the same gate drive circuit; or the compensation control signal may be generated by a a k-th stage shift register unit in a gate drive circuit, and the second reset control signal may be generated by a a (k+1)-th stage shift register unit in the gate drive circuit, where k is an integer greater than 0.

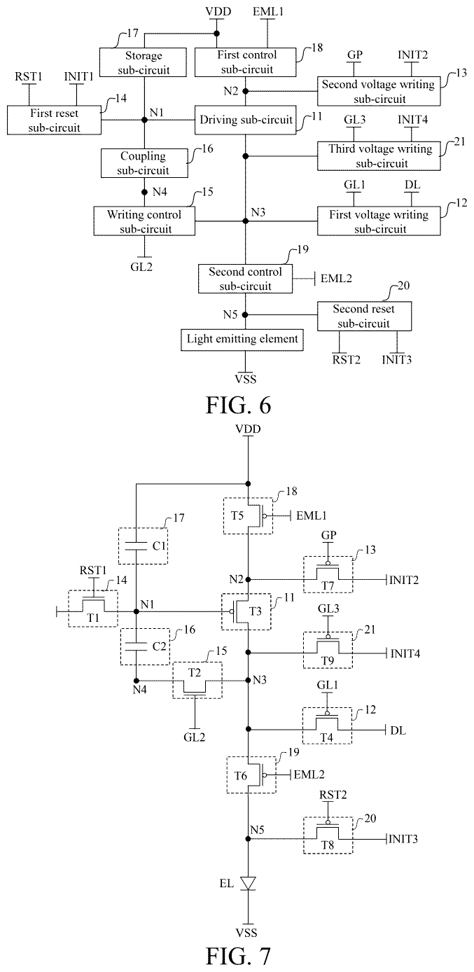

FIG. 4 is an equivalent circuit diagram of a pixel circuit according to at least one embodiment of the present disclosure. In some examples, as shown in FIG. 4, the driver sub-circuit 11 of the pixel circuit of the present example may include a third transistor (which may also be referred to as a driver transistor) T3; the first voltage writing sub-circuit 12 may include a fourth transistor (which may also be referred to as a data writing transistor) T4; the second voltage writing sub-circuit 13 may include a seventh transistor (which may also be referred to as a compensation control transistor) T7; the first reset sub-circuit 14 may include a first transistor (which may also be referred to as a first reset transistor) T1; the writing control sub-circuit 15 may include a second transistor (which may also be referred to as a compensation writing transistor) T2; the coupling circuit 16 may include a second capacitor C2; the storage sub-circuit 17 may include a first capacitor C1; the first control sub-circuit 18 may include a fifth transistor (which may also be referred to as a first control transistor) T5; the second control sub-circuit 19 may include a sixth transistor (which may also be referred to as a second control transistor) T6; and the second reset sub-circuit 20 may include an eighth transistor (which may also be referred to as a second reset transistor) T8.

In some examples, as shown in FIG. 4, a gate of the third transistor T3 is coupled with the first node N1, a first electrode of the third transistor T3 is coupled with the second node N2, and a second electrode of the third transistor T3 is coupled with the third node N3. The third transistor T3 is configured to provide a driving signal to the third node N3 under control of the first node N1. A gate of the first transistor T1 is coupled with the first reset control line RST1, a first electrode of the first transistor T1 is coupled with the first initial signal line INIT1, and a second electrode of the first transistor T1 is coupled with the first node N1. The first transistor T1 may be configured to write a first initial signal transmitted by the first initial signal line INIT1 to the first node N1 under the control of the first reset control line RST1. A gate of the second transistor T2 is coupled with the second control line GL2, a first electrode of the second transistor T2 is coupled with the third node N3, and a second electrode of the second transistor T2 is coupled with a fourth node N4. The second transistor T2 may be configured to conduct the third node N3 and the fourth node N4 under the control of the second scan line GL2 such that a signal of the third node N3 is written to the fourth node N4. A gate of the fourth transistor T4 is coupled the the first scan line GL1, a first electrode of the fourth transistor T4 is coupled with the data line DL, and a second electrode of the fourth transistor T4 is coupled with the third node N3. The fourth transistor T4 may be configured to write a data signal transmitted by the data line DL to the third node N3 under control of the first scan line GL1. A gate of the fifth transistor T5 is coupled with the first control line EML1, a first electrode of the fifth transistor T5 is coupled with the first power supply line VDD, and a second electrode of the fifth transistor T5 is coupled with the second node N2. The fifth transistor T5 may be configured to write a first voltage signal provided by the first power supply line VDD to the second node N2 under the control of the first control line EML1. A gate of the sixth transistor T6 is coupled with the second control line EML2, a first electrode of the sixth transistor T6 is coupled with the third node N3, and a second electrode of the sixth transistor T6 is coupled with the fifth node N5. The sixth transistor T6 may be configured to conduct the third node N3 and the fifth node N5 under the control of the second control line EML2. The gate of the seventh transistor T7 is coupled to the compensation control line GP, a first electrode of the seventh transistor T7 is coupled to the second initial signal line INIT2, and a second electrode of the seventh transistor T7 is coupled to the second node N2. The seventh transistor T7 may be configured to write a second initial signal transmitted by the second initial signal line INIT2 to the second node N2 under the control of the compensation control line GP. A gate of the first transistor T8 is coupled with the second reset control line RST2, a first electrode of the eighth transistor T8 is coupled with the third initial signal line INIT3, and a second electrode of the eighth transistor T8 is coupled with the fifth node N5. The eighth transistor T8 may be configured to write a third initial signal transmitted by the third initial signal line INIT3 to the fifth node N5 under the control of the second reset control line RST2. A first electrode of the first capacitor C1 is coupled to the first node N1, and a second electrode of the first capacitor C1 is coupled to the first power supply line VDD. The first capacitor C1 may be configured to store a voltage of the first node N1. A first electrode of the second capacitor C2 is coupled to the fourth node N4, and a second electrode of the second capacitor C2 is coupled to the first node N1. The second capacitor C2 may be configured to couple a signal written to the fourth node N4 to the first node N1. A first electrode of the light emitting element EL is coupled with the fifth node N5, and a second electrode of the light emitting element EL is coupled with the second power supply line VSS.

In some examples, as shown in FIG. 4, the first node N1 is a connection point for the first transistor T1, the third transistor T3, the first capacitor C1, and the second capacitor C2; the second node N2 is a connection point for the third transistor T3, the seventh transistor T7, and the fifth transistor T5; the third node N3 is a connection point for the second transistor T2, the third transistor T3, the fourth transistor T4, and the sixth transistor T6; the fourth node N4 is a connection point for the second capacitor C2 and the second transistor T2; and the fifth node N5 is a connection point for the sixth transistor T6, the eighth transistor T8 and the light emitting element EL.

In some examples, as shown in FIG. 4, the third transistor T3, the fourth transistor T4, the fifth transistor T5, the sixth transistor T6, the seventh transistor T7, and the eighth transistor T8 in the pixel circuit may be a first type of transistors, and the first transistor T1 and the second transistor T2 may be a second type of transistors. The transistor types of the first type of transistors and the second type of transistors may be different. In some examples, the first type of transistors may be P-type transistors, which may adopt, for example, low temperature polysilicon thin film transistors, and the second type of transistors may be N-type transistors, which may adopt, for example, oxide thin film transistors. An active layer of a Low Temperature Poly-Silicon thin film transistor may be made of Low Temperature Poly-Silicon (LTPS), and an active layer of an oxide thin film transistor may be made of an oxide semiconductor (Oxide). A Low Temperature Poly Silicon thin film transistor has advantages such as a high mobility rate and fast charging, and an oxide thin film transistor has an advantage such as a low leakage current. The Low Temperature Poly Silicon thin film transistors and the oxide thin film transistors are integrated on one display substrate to form a Low Temperature Polycrystalline Oxide (LTPO) display substrate, and the advantages of both the Low Temperature Poly Silicon thin film transistor and the oxide thin film transistor may be utilized, which may reduce power consumption, and improve display quality. The first transistor T1 and the second transistor T2 of this example adopt oxide thin film transistors, which may be beneficial to reducing occurrence of current leakage at the first node and the fourth node.

Exemplary structures of the drive sub-circuit 11, the first voltage writing sub-circuit 12, the second voltage writing sub-circuit 13, the writing control sub-circuit 15, the coupling sub-circuit 16, the storage sub-circuit 17, the first reset sub-circuit 14, the second reset sub-circuit 20, the first control sub-circuit 18, and the second control sub-circuit 19 are shown in FIG. 4. It is easy for those skilled in the art to understand that the implementation of the above sub-circuits is not limited thereto, as long as the corresponding functions may be achieved.

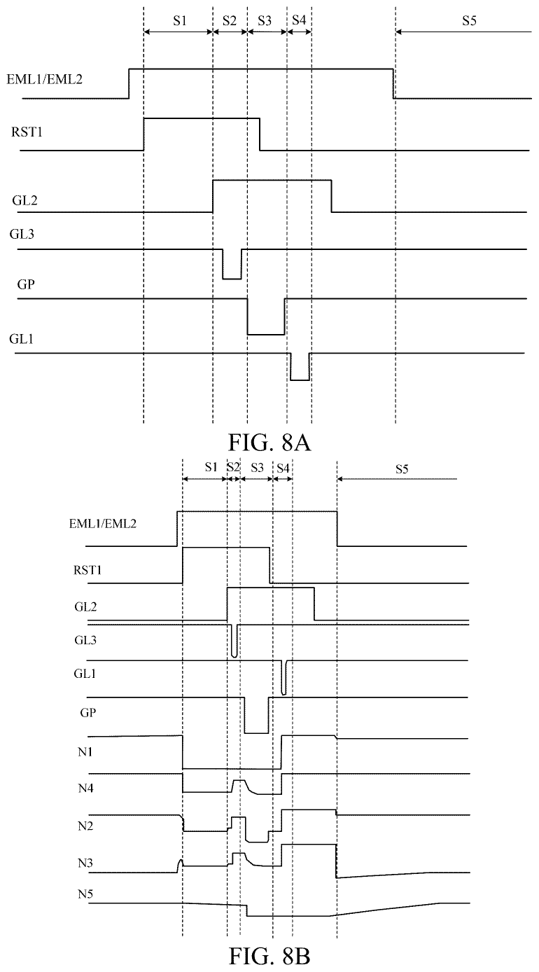

FIGS. 5A and 5B are working timing diagrams of the pixel circuit shown in FIG. 4. FIG. 5B illustrates simulation results from the first node N1 to the fifth node N5. In FIG. 5B, in one display period, a duration of an effective level signal of the compensation control signal is five times (i.e., 5H) the data writing time length (1H), and the data writing time length may be the same as a duration of an effective level signal of the first scan signal.

In some examples, as shown in FIG. 4, the pixel circuit of the present example may include eight transistors (i.e., the first transistors T1 to the eighth transistors T8), two capacitance units (i.e., the first capacitor C1 and the second capacitor C2), nine input terminals (i.e., the data line DL, the first scan line GL1, the second scan line GL2, the first reset control line RST1, the second reset control line RST2, the compensation control line GP, the first initial signal line INIT1, the second initial signal line INIT2, the third initial signal line INIT3), and two power supply terminals (i.e., the first power supply line VDD and the second power supply line VSS).

In some examples, as shown in FIGS. 5A and 5B, in one display period, a working process of the pixel circuit may include following stages. In this example, the second reset control signal may be the same as the compensation control signal.

In the first stage S1, the first control signal provided by the first control line EML1 is at a low level, and the fifth transistor T5 is in an on state. The second control signal provided by the second control line EML2 is at a high level, and the sixth transistor T6 is in an off state. The first scan signal provided by the first scan line GL1 is at a high level, and the fourth transistor T4 is in an off state. The second scan signal provided by the second scan line GL2 is at a low level, and the second transistor T2 is in an off state. The compensation control signal provided by the compensation control line GP is at a high level, and the seventh transistors T7 and the eighth transistors T8 are in an off state. The first reset control signal provided by the first reset control line RST1 is at a high level, the first transistor T1 is turned on to write the first initial signal transmitted by the first initial signal line INIT1 to the first node N1, and a voltage of the first node N1 is reset by using the first initial signal such that the voltage of the first node N1 is Vn1=Vinit1. Herein, Vinit1 is a first initial signal. A voltage value of the first initial signal may be less than 0.

In the second stage S2, the first control signal provided by the first control line EML1 is still at a low level, and the fifth transistor T5 is continuously in an on state. The second control signal provided by the second control line EML2 is still at the high level, and the sixth transistor T6 is continuously in an off state. The first scan signal provided by the first scan line GL1 is at a high level, and the fourth transistor T4 is continuously in an off state. The second scan signal provided by the second scan line GL2 is switched to a high-level signal, and the second transistor T2 is turned on to conduct the third node N3 and the fourth node N4. The compensation control signal provided by the compensation control line GP is still at a high level, and the seventh transistors T7 and the eighth transistors T8 are continuously in an off state. The first reset control signal provided by the first reset control line RST1 is still at a high level, and the first transistor T1 is continuously in an on state.

In the second stage S2, the first transistor T1 is in an on state and writes the first initial signal to the first node N1. The first voltage signal Vdd provided by the first power supply line VDD may be written to the fourth node N4 through the turned-on fifth transistor T5, the second node N2, the turned-on third transistor T3, the third node N3, and the turned-on second transistor T2 sequentially to charge a potential of the fourth node N4, such that the voltage of the fourth node N4 is Vn4=Vdd.

The third stage S3 may also be referred to as a threshold compensation stage. The first control signal provided by the first control line EML is switched to a high-level signal, and the fifth transistor T5 is turned off. The second control signal provided by the second control line EML2 is still at a high level, and the sixth transistor T6 is still in an off state. The first scan signal provided by the first scan line GL1 is still at a high level, and the fourth transistor T4 is continuously in an off state. The second scan signal provided by the second scan line GL2 is still at a high level, and the second transistor T2 is continuously in an on state. The compensation control signal provided by the compensation control line GP is switched to a low-level signal, and the seventh transistors T7 and the eighth transistors T8 are turned on. The first reset control signal provided by the first reset control line RST1 is still at a high level, and the first transistor T1 is continuously in an on state.

In the third stage S3, the first transistor T1 is in an on state and writes the first initial signal to the first node N1. The second initial signal provided by the second initial signal line INIT2 is written to the fourth node N4 through the turned-on seventh transistor T7, the second node N2, the turned-on third transistor T3, the third node N3, and the turned-on second transistor T2 sequentially, and the writing compensation is performed on the threshold voltage of the third transistor T3. In this stage, the third transistor T3 may be charged in reverse by using the fourth node N4 until a potential of the fourth node N4 is Vn4=Vinit1−Vth, such that a voltage difference between a gate electrode and a first electrode of the third transistor T3 is Vgs=Vth, herein Vth is a threshold voltage of the third transistor T3. In this stage, the threshold voltage of the third transistor may be fully written to the fourth node N4.

In the third stage S3, the eighth transistor T8 is turned on to write the third initial signal provided by the third initial signal line INIT3 to the fifth node N5 to initialize the fifth node N5.

The fourth stage S4 may also be referred to as a data writing stage. The first control signal provided by the first control line EML1 is continuously at a high level, and the fifth transistor T5 is still in an off state. The second control signal provided by the second control line EML2 is continuously at a high level, and the sixth transistor T6 is still in an off state. The first scan signal provided by the first scan line GL1 is switched to a low-level signal, and the fourth transistor T4 is turned on. The second scan signal provided by the second scan line GL2 is still at a high level, and the second transistor T2 is in an on state. The compensation control signal provided by the compensation control line GP is switched to a high-level signal, and the seventh transistors T7 and the eighth transistors T8 are turned off. The first reset control signal provided by the first reset control line RST1 is at a low level, and the first transistor T1 is turned off.

In the fourth stage S4, the first transistor T1 is turned off and the fourth transistor T4 is turned on, and the data signal transmitted by the data line DL may be written to the fourth node N4 through the turned-on fourth transistor T4, the third node N3, and the turned-on second transistor T2 sequentially. At this time, a jump voltage of the fourth node N4 is ΔVn4=Vdata−(Vinit1−Vth), where Vdata is a voltage value of the data signal. Through coupling action of the second capacitor C2, the jump voltage of the fourth node N4 may be written to the first node, such that the voltage the first node is Vn1=Vinit1+(Vdata−(Vinit1−Vth))=Vdata+Vth.

After the fourth stage S4 and before the fifth stage S5, the first control signal provided by the first control line EML1 and the second control signal provided by the second control line EML2 may be continuously at a high level, and the fifth transistors T5 and the sixth transistors T6 are in an off state. The first scan signal provided by the first scan line GL1 is continuously at a high level, and the fourth transistor T4 is in an off state. The second scan signal provided by the second scan line GL2 may be switched from a high-level signal to a low-level signal, and the second transistor T2 is turned off. The compensation control signal provided by the compensation control line GP is continuously at a high level, and the seventh transistors T7 and the eighth transistors T8 are in an off state. The first reset control signal provided by the first reset control line RST1 is continuously at a low level, and the first transistor T1 is in an off state.

The fifth stage S5 may also be referred to as a light emitting stage. The first control signal provided by the first control line EML1 and the second control signal provided by the second control line EML2 are switched to low level signals, and both the fifth transistor T5 and the sixth transistor T6 are turned on. The first scan signal provided by the first scan line GL1 is at a high level, and the fourth transistor T4 is in an off state. The second scan signal provided by the second scan line GL2 is at a low level, and the second transistor T2 is in an off state. The compensation control signal provided by the compensation control line GP is at a high level, and the seventh transistors T7 and the eighth transistors T8 are in an off state. The first reset control signal provided by the first reset control line RST1 is at a low level, and the first transistor T1 is in an off state.

In the fifth stage S5, the first voltage signal outputted by the first power supply line VDD may provide a driving signal to the first electrode of the light emitting element EL through the turned-on fifth transistor T5, the turned-on third transistor T3, and the turned-on sixth transistor T6 to drive the light emitting element EL to emit light.

During a driving process of the pixel circuit, a driving current flowing through the third transistor T3 is determined by a voltage difference between the gate electrode and the first electrode of the third transistor T3. Since the voltage of the first node N1 is Vn1=Vdata+Vth, the driving current of the third transistor T3 is:

$$I = 0.5 \times K \times {( Vgs - Vth )}^{2} = 0.5 \times K \times {( Vdata + Vth - Vdd - Vth )}^{2} = 0.5 \times K \times {( Vdata - Vdd )}^{2} .$$

Herein, K is a constant, Vgs is a voltage difference between the gate electrode and the first electrode of the third transistor T3, Vth is a threshold voltage of the third transistor T3, Vdata is a voltage value of a data signal transmitted by the data line DL, and Vdd is a first voltage signal output from the first power supply line VDD.

It can be seen that the driving current flowing through the light emitting element is independent of the threshold voltage of the third transistor T3, and only depends on the data signal provided by the data line and the first voltage signal provided by the first power supply line. The pixel circuit of the present example may achieve compensation for the threshold voltage of the third transistor T3, eliminate an influence of the threshold voltage of the third transistor T3 on the driving current, thereby ensuring a uniformity of a display brightness of the display substrate, and improving a display effect.

In some examples, within a duration of an effective level signal of the compensation control signal, writing of the compensation for the threshold voltage of the driving transistor may be completed, and within a duration of an effective level signal of the first scan signal, writing of the data signal may be completed. For example, in one display period, the duration of the effective level signal of the compensation control signal may be five times or ten times or twenty times the duration of the effective level signal of the first scan signal. By controlling writing of the compensation for the threshold voltage and writing of the data signal separately, it is beneficial to reducing a writing time length of the data writing, and increasing a compensation time length of the threshold voltage, such that the compensation for the threshold voltage is not affected by a writing process of the data signal, and the complete compensation for the threshold voltage may be achieved at a high refresh rate, thereby facilitating supporting a display product with a high refresh rate, and improving a display brightness and a display uniformity.

In some examples, when the pixel circuit is applied to a display scene with a low frequency, the first reset control signal and the second scan signal driven by a low frequency may be used, and the compensation control signal, the first scan signal, the first control signal and the second control signal driven by a high frequency may be used.

In some examples, the display substrate may include five different gate drive circuits (e.g. including a first gate drive circuit, a second gate drive circuit, a third gate drive circuit, a fourth gate drive circuit, and a fifth gate drive circuit). For example, the first control signal may be generated by the first gate drive circuit, the second control signal may be generated by the second gate drive circuit, the compensation control signal and the second reset control signal may be generated by the third gate drive circuit, the first scan signal may be generated by the fourth gate drive circuit, and the second scan signal and the first reset control signal may be generated by the fifth gate drive circuit. For example, the first reset control signal received by a pixel circuit may be generated by an n-th stage shift register unit in the fifth gate drive circuit, and the second scan signal received by the pixel circuit may be generated by an (n+7)-th stage shift register unit in the fifth gate drive circuit, where n may be a natural number. A duration of an effective level signal (e.g., a low level signal) of the compensation control signal may be adjustable, for example, the duration of the effective level signal of the compensation control signal may be flexibly adjusted according to charging requirements.

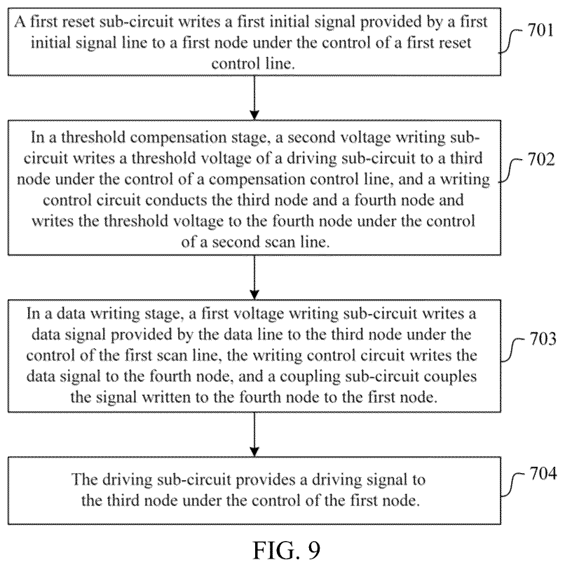

FIG. 6 is a schematic diagram of another structure of a pixel circuit according to at least one embodiment of the present disclosure. In some examples, as shown in FIG. 6, the pixel circuit of the present embodiment may include a driving sub-circuit 11, a first voltage writing sub-circuit 12, a second voltage writing sub-circuit 13, a first reset sub-circuit 14, a writing control sub-circuit 15, a coupling sub-circuit 16, a storage sub-circuit 17, a first control sub-circuit 18, a second control sub-circuit 19, a second reset sub-circuit 20, and a third voltage writing sub-circuit 21. The third voltage writing sub-circuit 21 is coupled to the third node N3, the third scan line GL3, and the fourth initial signal line INIT4, and is configured to write the fourth initial signal provided by the fourth initial signal line INIT4 to the third node N3 under the control of the third scan line GL3 before the threshold compensation stage. Rest of the structure of the pixel circuit according to this example may refer to descriptions of the aforementioned embodiments, and thus will not be repeated here.

In some examples, the first control signal provided by the first control line EML1 may be the same as the second control signal provided by the second control line EML2. In the present example, a working timing of the first control sub-circuit 18 may be the same as a working timing of the second control sub-circuit 19.

In some examples, the first initial signal provided by the first initial signal line INIT1 may be the same as the second initial signal provided by the second initial signal line INIT2, and the fourth initial signal provided by the fourth initial signal line INIT4 may be larger than the first initial signal provided by the first initial signal line INIT1. For example, a voltage value of the fourth initial signal may be positive, and a voltage value of the first initial signal may be negative. In the present example, the fourth initial signal may be used to charge the fourth node before the threshold compensation stage, and charge the drive sub-circuit in reverse by using a voltage of the fourth node in the threshold compensation stage, so as to achieve writing of the compensation for the threshold voltage.

In some examples, in one display period, a duration of an effective level signal of the first scan signal provided by the first scan line GL1 may be the same as a duration of an effective level signal of the third scan signal provided by the third scan line GL3. An end time of the effective level signal of the third scan signal may be earlier than a start time of the effective level signal of the first scan signal. In some examples, the first scan signal and the third scan signal may be provided by the same gate drive circuit, for example, an m-th stage shift register unit in one gate drive circuit provides the third scan signal, an (m+7)-th stage shift register unit in the gate drive circuit may provide the first scan signal, where m may be a natural number. The present embodiment is not limited thereto.

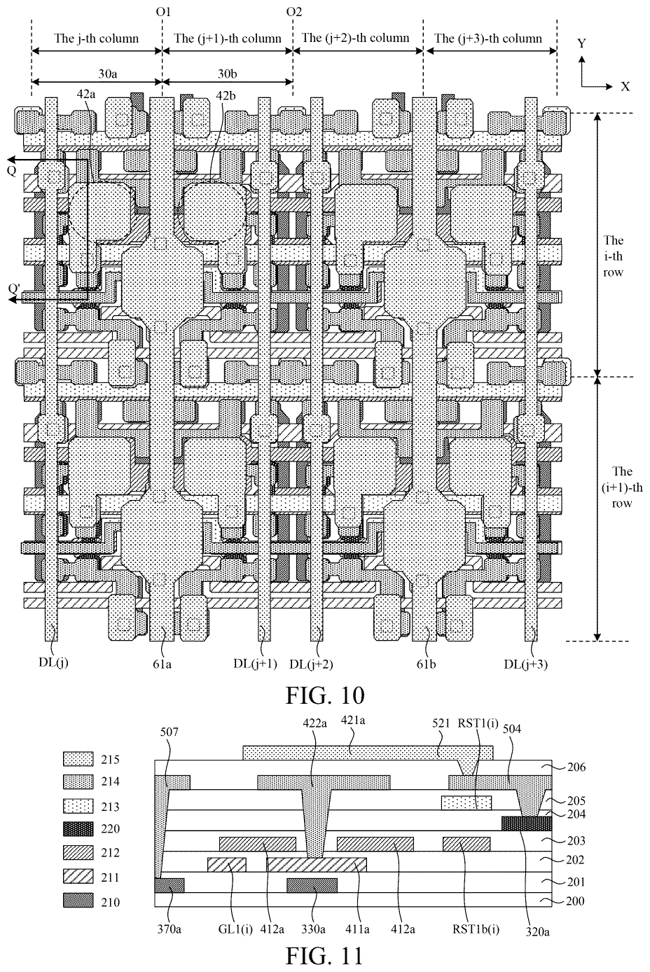

FIG. 7 is another equivalent circuit diagram of a pixel circuit according to at least one embodiment of the present disclosure. In some examples, as shown in FIG. 7, the driver sub-circuit 11 of the pixel circuit of the present example may include a third transistor T3; the first voltage writing sub-circuit 12 may include a fourth transistor T4; the second voltage writing sub-circuit 13 may include a seventh transistor T7; the first reset sub-circuit 14 may include a first transistor T1; the writing control sub-circuit 15 may include a second transistor T2; the coupling circuit 16 may include a second capacitor C2; the storage sub-circuit 17 may include a first capacitor C1; the first control sub-circuit 18 may include a fifth transistor T5; the second control sub-circuit 19 may include a sixth transistor T6; the second reset sub-circuit 20 may include an eighth transistor T8; and the third voltage writing sub-circuit 21 may include a ninth transistor T9.

In some examples, as shown in FIG. 7, a gate of the ninth transistor T9 is coupled to the third scan line GL3, a first electrode of the ninth transistor T9 is coupled to the fourth initial signal line INIT4, and a second electrode of the ninth transistor T9 is coupled to the third node N3. The ninth transistor T9 may be configured to write a fourth initial signal transmitted by the fourth initial signal line INIT4 to the third node N3 under the control of the third scan line GL3. A connection relationship between the remaining transistors and capacitors of the pixel circuit of this example may be as described above, and will not be described here in detail.

In some examples, as shown in FIG. 7, the first node N1 is a connection point for the first transistor T1, the third transistor T3, the first capacitor C1, and the second capacitor C2; the second node N2 is a connection point for the third transistor T3, the seventh transistor T7, and the fifth transistor T5; the third node N3 is a connection point for the second transistor T2, the third transistor T3, the fourth transistor T4, the sixth transistor T6, and the ninth transistor T9; the fourth node N4 is a connection point between the second capacitor C2 and the second transistor T2; and the fifth node N5 is a connection point for the sixth transistor T6, the eighth transistor T8, and the light emitting element EL.

In some examples, as shown in FIG. 7, the third transistor T3, the fourth transistor T4, the fifth transistor T5, the sixth transistor T6, the seventh transistor T7, the eighth transistor T8, and the ninth transistor T9 in the pixel circuit may be the first type of transistors, such as P-type transistors; and the first transistors T1 and the second transistors T2 may be the second type of transistors, such as N-type transistors.

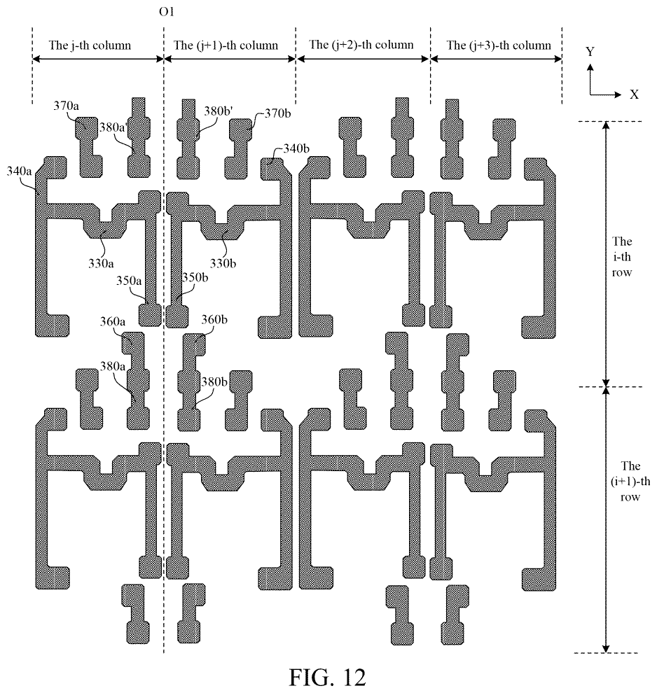

FIGS. 8A and 8B are working timing diagrams of the pixel circuit shown in FIG. 7. FIG. 8B illustrates simulation results of the first nodes N1 to the fifth nodes N5. In some examples, as shown in FIG. 7, the pixel circuit of the present example may include nine transistors (i.e., the first transistors T1 to the ninth transistors T9), two capacitance units (i.e., the first capacitor C1 and the second capacitor C2), tenth input terminals (i.e., the data line DL, the first scan line GL1, the second scan line GL2, the third scan line GL3, the first reset control line RST1, the compensation control line GP, the first initial signal line INIT1, the second initial signal line INIT2, the third initial signal line INIT3 and the fourth initial signal line INIT4), and two power supply terminals (i.e., the first power supply line VDD and the second power supply line VSS).

In some examples, as shown in FIGS. 8A and 8B, in one display period, a working process of the pixel circuit may include following stages. In this example, the second reset control signal and the compensation control signal are the same.

In the first stage S1, the first control signal provided by the first control line EML1 and the second control signal provided by the second control line EML2 are both at a high level, and the fifth transistors T5 and the sixth transistors T6 are turned off. The second scan signal provided by the second scan line GL2 is at a low level, and the second transistor T2 is in an off state. The first scan signal provided by the first scan line GL1 is at a high level, and the fourth transistor T4 is in an off state. The third scan signal provided by the third scan line GL3 is at a high level, and the ninth transistor T9 is in an off state. The compensation control signal provided by the compensation control line GP is at a high level, and the seventh transistors T7 and the eighth transistors T8 are in an off state. The first reset control signal provided by the first reset control line RST1 is at a high level, the first transistor T1 is turned on to write the first initial signal transmitted by the first initial signal line INIT1 to the first node N1, and a voltage of the first node N1 is reset by using the first initial signal such that the voltage of the first node N1 is Vn1=Vinit1. Herein, Vinit1 is a voltage value of the first initial signal. A voltage value of the first initial signal may be less than 0.

In the second stage S2, the first control signal provided by the first control line EML1 and the second control signal provided by the second control line EML2 are both at a high level, and the fifth transistors T5 and the sixth transistors T6 are in an off state. The first scan signal provided by the first scan line GL1 is at a high level, and the fourth transistor T4 is continuously in an off state. The second scan signal provided by the second scan line GL2 is switched to a high-level signal, and the second transistor T2 is turned on to conduct the third node N3 and the fourth node N4. The compensation control signal provided by the compensation control line GP is still at a high level, and the seventh transistors T7 and the eighth transistors T8 are continuously in an off state. The first reset control signal provided by the first reset control line RST1 is still at a high level, and the first transistor T1 is continuously in an on state. The third scan signal provided by the third scan line GL3 is switched to a low-level signal, the ninth transistor T9 is turned on, and the fourth initial signal provided by the fourth initial signal line INIT4 may be written to the fourth node N4 through the turned-on ninth transistor T9, the third node N3, and the turned-on second transistor T2 sequentially to charge a potential of the fourth node N4, such that the voltage of the fourth node N4 is Vn4=Vinit4, wherein Vinit4 is the fourth initial signal, and a voltage value of the fourth initial signal may be greater than 0.

The third stage S3 may also be referred to as a threshold compensation stage. The first control signal provided by the first control line EML1 and the second control signal provided by the second control line EML2 are both at a high level, and the fifth transistors T5 and the sixth transistors T6 are in an off state. The first scan signal provided by the first scan line GL1 is at a high level, and the fourth transistor T4 is continuously in an off state. The second scan signal provided by the second scan line GL2 is at a high level, and the second transistor T2 is in an on state to conduct the third node N3 and the fourth node N4. The third scan signal provided by the third scan line GL3 is at a high level, and the ninth transistor T9 is in an off state. The compensation control signal provided by the compensation control line GP is switched to a low-level signal, and the seventh transistors T7 and the eighth transistors T8 are turned on. The first reset control signal provided by the first reset control line RST1 is still at a high level, and the first transistor T1 is continuously in an on state.

In the third stage S3, the second initial signal provided by the second initial signal line INIT2 may be written to the fourth node N4 through the turned-on seventh transistor T7, the second node N2, the turned-on third transistor T3, the third node N3, and the turned-on second transistor T2 sequentially to write compensation for the threshold voltage of the third transistor T3. In this stage, the third transistor T3 may be charged in reverse by using the fourth node N4 until a potential of the fourth node N4 is Vn4=Vinit1−Vth, such that a voltage difference between a gate electrode and a first electrode of the third transistor T3 is Vgs=Vth, herein Vth is a threshold voltage of the third transistor T3. In this stage, the threshold voltage of the third transistor may be fully written to the fourth node N4.

The fourth stage S4 may also be referred to as a data writing stage. The first control signal provided by the first control line EML1 and the second control signal provided by the second control line EML2 are both at a high level, and the fifth transistors T5 and the sixth transistors T6 are in an off state. The first reset control signal provided by the first reset control line RST1 is switched to a low-level signal, and the first transistor T1 is turned off. The second scan signal provided by the second scan line GL2 is at a high level, and the second transistor T2 is in an on state to conduct the third node N3 and the fourth node N4. The third scan signal provided by the third scan line GL3 is at a high level, and the ninth transistor T9 is in an off state. The compensation control signal provided by the compensation control line GP is switched to a high-level signal, and the seventh transistors T7 and the eighth transistors T8 are turned off. The first scan signal provided by the first scan line GL1 is switched to a low-level signal, the fourth transistor T4 is turned on, and the data signal transmitted by the data line DL may be written to the fourth node N4 through the turned-on fourth transistor T4, the third node N3, and the turned-on second transistor T2 sequentially. At this time, a jump voltage of the fourth node N4 is ΔVn4=Vdata−(Vinit1−Vth), herein Vdata is a voltage value of the data signal. Through coupling action of the second capacitor C2, the jump voltage of the fourth node N4 may be written to the first node, such that the voltage the first node is Vn1=Vinit1+(Vdata−(Vinit1−Vth))=Vdata+Vth.

The fifth stage S5 may also be referred to as a light emitting stage. The first control signal provided by the first control line EML1 and the second control signal provided by the second control line EML2 are switched to low level signals, and both the fifth transistor T5 and the sixth transistor T6 are turned on. The first scan signal provided by the first scan line GL1 is at a high level, and the fourth transistor T4 is in an off state. The second scan signal provided by the second scan line GL2 is at a low level, and the second transistor T2 is in an off state. The compensation control signal provided by the compensation control line GP is at a high level, and the seventh transistors T7 and the eighth transistors T8 are in an off state. The first reset control signal provided by the first reset control line RST1 is at a low level, and the first transistor T1 is in an off state. The third scan signal provided by the third scan line GL3 is at a high level, and the ninth transistor T9 is in an off state.

During a driving process of the pixel circuit, a driving current flowing through the third transistor T3 is determined by a voltage difference between the gate electrode and the first electrode of the third transistor T3. Since the voltage of the first node N1 is Vn1=Vdata+Vth, the driving current of the third transistor T3 is:

$$I = 0.5 \times K \times {( Vgs - Vth )}^{2} = 0.5 \times K \times {( Vdata + Vth - Vdd - Vth )}^{2} = 0.5 \times K \times {( Vdata - Vdd )}^{2} .$$

In some examples, in one display period, a duration of an effective level signal (e.g., a high level signal) of the second scan signal provided by the second scan line GL2 may be greater than a sum of a duration of an effective level signal (e.g., a low level signal) of the first scan signal, a duration of an effective level signal (e.g., a low level signal) of the third scan signal, and a duration of an effective level signal (e.g., a low level signal) of the compensation control signal. In this example, charging of the fourth node N4, writing of the threshold voltage to the fourth node N4, and writing of the data signal are written all through a path where the second transistor T2 is located.

In some examples, the display substrate may include four different gate drive circuits. For example, the first control signal and the second control signal may be generated by the same gate drive circuit, the first scan signal and the third scan signal may be generated by the same gate drive circuit, the second scan signal and the first reset control signal may be generated by the same gate drive circuit, and the compensation control signal may be generated by one gate drive circuit. For example, the first control signal and the second control signal received by one pixel circuit may be generated by a same stage shift register unit in the same gate drive circuit. For example, the third scan signal received by one pixel circuit may be generated by an m-th stage shift register unit in one gate drive circuit, and the first scan signal received by the pixel circuit may be generated by an (m+7)-th stage shift register unit in the gate drive circuit, where m may be a natural number. For the rest of the description about the working timing of the pixel circuit of this example, reference may be made to the description of the foregoing embodiments, so details are not repeated here.

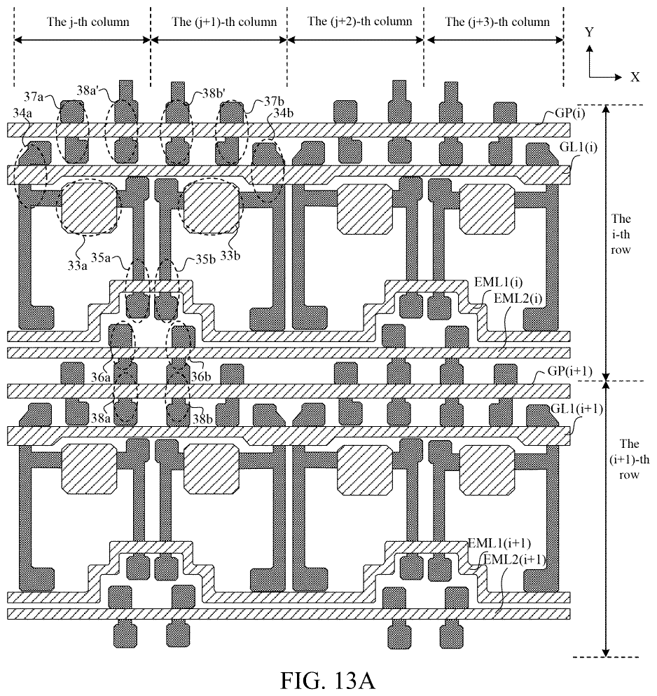

FIG. 9 is a flowchart of a method for driving a pixel circuit according to at least one embodiment of the present disclosure. In some examples, as shown in FIG. 9, the method for driving the pixel circuit according to an embodiment of the present disclosure may include following acts.

At act 701, a first reset sub-circuit writes a first initial signal provided by a first initial signal line to a first node under the control of a first reset control line.

At act 702, in a threshold compensation stage, a second voltage writing sub-circuit writes a threshold voltage of a driving sub-circuit to a third node under the control of a compensation control line, and a writing control circuit conducts the third node and a fourth node and writes the threshold voltage to the fourth node under the control of a second scan line.

At act 703, in a data writing stage, a first voltage writing sub-circuit writes a data signal provided by the data line to the third node under the control of the first scan line, the writing control circuit writes the data signal to the fourth node, and a coupling sub-circuit couples the signal written to the fourth node to the first node.

At act 704, the driving sub-circuit provides a driving signal to the third node under the control of the first node.

In some examples, in one display period, the threshold compensation stage may be before the data writing stage, and a time length of the threshold compensation stage may be greater than a time length of the data writing stage.

In some examples, the method for driving in the present example may also include that a first control sub-circuit charges the fourth node with a first voltage signal provided by a first power supply line under the control of a first control line before the threshold compensation stage.

In some examples, the pixel circuit also includes a third voltage writing sub-circuit, which is coupled to the third node, a third scan line, and a fourth initial signal line. The method for driving in the present example may also include that before the threshold compensation stage, the third voltage writing sub-circuit charges the fourth node with a fourth initial signal provided by the fourth initial signal line under control of the third scan line; herein the fourth initial signal is greater than the second initial signal.

In some examples, in one display period, a duration of an effective level signal of a second scan signal provided by the second scan line is greater than a sum of a duration of an effective level signal of a first scan signal provided by the first scan line, a duration of an effective level signal of a third scan signal provided by the third scan line, and a duration of an effective level signal of a compensation control signal provided by the compensation control line.

For the description of the method for driving the pixel circuit of this embodiment, reference may be made to the description of the foregoing embodiments, so details will not be repeated here.

The present embodiment also provides a display substrate, including a base substrate and a circuit structure layer disposed on the base substrate. The circuit structure layer includes a plurality of pixel circuits, and at least one pixel circuit includes a first capacitor and a second capacitor. The second capacitor is located on a side of the first capacitor away from the base substrate, and an orthographic projection of the second capacitor on the base substrate is at least partially overlapped with an orthographic projection of the first capacitor on the base substrate. The first capacitor includes a first electrode plate and a second electrode plate, and the second capacitor includes a third electrode plate and a fourth electrode plate. The second electrode plate of the first capacitor is located on a side of the first electrode plate away from the base substrate, the third electrode plate of the second capacitor is located on a side of the fourth electrode plate away from the base substrate, and the fourth electrode plate of the second capacitor is located on a side of the second electrode plate of the first capacitor away from the base substrate; and the first electrode plate of the first capacitor is connected to the fourth electrode plate of the second capacitor.

In the display substrate according to the present embodiment, two capacitors having a connection relationship included in the pixel circuit are stacked, so that the occupied space of the pixel circuit may be saved, so as to achieve a high-resolution display substrate.

In some exemplary implementations, the second electrode plate of the first capacitor may have a hollow region, and an orthographic projection of a connection position between the first electrode plate and the fourth electrode plate on the base substrate may be located within a range of an orthographic projection of the hollow region on the base substrate. In the present example, an electrical connection between the first electrode plate and the fourth electrode plate is achieved by providing a hollow region on the second electrode plate. However, the present embodiment is not limited thereto. In other examples, the second electrode plate may have a recess portion, and the fourth electrode plate may be electrically connected to the first electrode plate at a position corresponding to the recess portion.

In some exemplary implementations, an orthographic projection of the third electrode plate of the second capacitor on the base substrate may cover orthographic projections of the first electrode plate and the fourth electrode plate on the base substrate. In this example, the third electrode plate is provided to cover the first electrode plate and the fourth electrode plate, which is beneficial to ensuring a potential stability of the node to which the first electrode plate and the fourth electrode plate are connected.

In some exemplary implementations, second electrode plates of first capacitors of a plurality of pixel circuits disposed along a first direction may be of an integral structure connected to each other, and the integral structure may be connected to a first power supply line extending along a second direction to form a mesh structure for transmitting a first voltage signal. The first power supply line may be located on a side of the integral structure away from the base substrate. Herein, the first direction may intersect with the second direction, for example, the first direction may be perpendicular to the second direction. According to the present example, by forming a mesh structure for transmitting the first voltage signal, it is beneficial to a transmission uniformity of the first voltage signal.

In some exemplary implementations, the integral structure formed by connecting the second electrode plates of the first capacitors of the plurality of pixel circuits disposed along the first direction may be connected to the first power supply line through a ninth connection electrode, and the ninth connection electrode may be located on a side of the integral structure away from the base substrate and located on a side of the first power supply line close to the base substrate. For example, the second electrode plate may be located in the second conductive layer, the ninth connection electrode may be located in the fourth conductive layer, and the first power supply line may be located in the fifth conductive layer.

In some exemplary implementations, the pixel circuit is connected to a first initial signal line, a second initial signal line and a third initial signal line. The first initial signal line, the second initial signal line, and the third initial signal line may be located in different conductive layers. In this example, the first initial signal line, the second initial signal line, and the third initial signal line are disposed in different conductive layers, which may be beneficial to saving disposement space of traces.

In some exemplary implementations, the pixel circuit may include at least one first type of transistor and at least one second type of transistor. In a direction perpendicular to the display substrate, the circuit structure layer may include a first semiconductor layer, a first conductive layer, a second conductive layer, a second semiconductor layer, a third conductive layer, a fourth conductive layer, and a fifth conductive layer which are disposed on the base substrate. The first semiconductor layer may include an active layer of at least one first type of transistor, and the second semiconductor layer may include an active layer of at least one second type of transistor.

In some exemplary implementations, the first electrode plate of the first capacitor may be located in the first conductive layer, and the second electrode plate of the first capacitor may be located in the second conductive layer; the third electrode plate of the second capacitor may be located in the fifth conductive layer, and the fourth electrode plate of the second capacitor may be located in the fourth conductive layer. In this example, the first capacitor and the second capacitor are stacked along a direction perpendicular to the display substrate, so that the occupied space of the two capacitors may be saved.

In some exemplary implementations, the pixel circuit is electrically connected to the first initial signal line which may be located in the fourth conductive layer, and an orthographic projection of the first initial signal line on the base substrate may be at least partially overlapped with orthographic projections of traces located in the second conductive layer and the third conductive layer on the base substrate. In this example, the disposement space of traces may be saved by disposing the first initial signal line and the traces of the remaining conductive layers to be stacked.

In some exemplary implementations, the pixel circuit is electrically connected to a second initial signal line and a third initial signal line; and the third initial signal line may be located in the second conductive layer, the second initial signal line may be located in the third conductive layer, and orthographic projections of the second initial signal line and the third initial signal line on the base substrate may be at least partially overlapped. In this example, the second initial signal line and the third initial signal line located in different conductive layers are disposed to be stacked, so that the the disposement space of traces may be saved.

In some exemplary implementations, the plurality of pixel circuits may be divided into a plurality of pixel circuit groups, each pixel circuit group includes two pixel circuits disposed to be adjacent along the first direction, and the two pixel circuits in the pixel circuit group are disposed symmetrically with respect to a first centerline of the pixel circuit group in the first direction. In the present disclosure, “symmetrically” may refer to a case that a boundary is defined not so strictly and an approximately symmetrical disposement within a range of a process and measurement error is allowed. In the present example, the pixel circuits are disposed symmetrically, so that the occupied space of the pixel circuits may be saved.

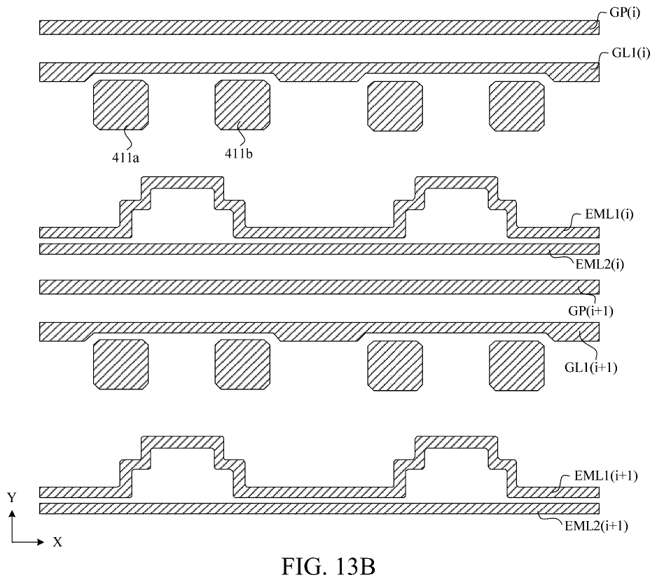

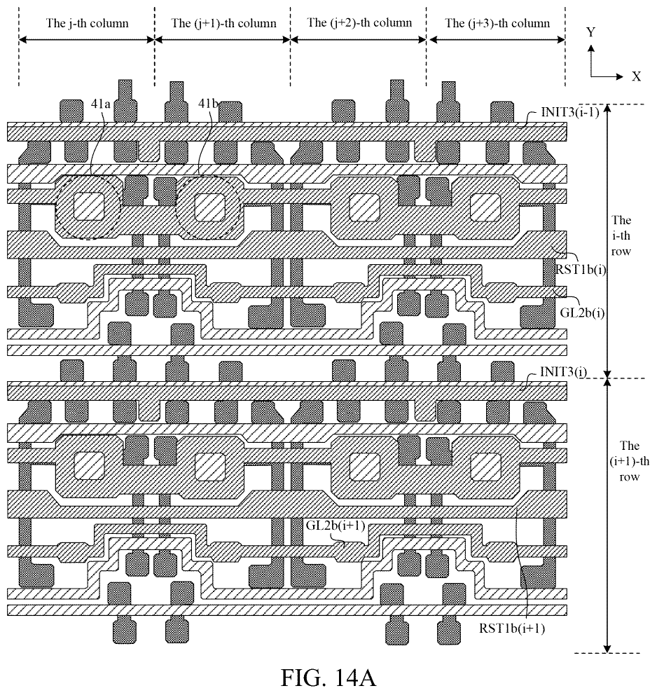

FIG. 10 is a schematic diagram of a partial plan structure of a circuit structure layer of a display substrate according to at least one embodiment of the present disclosure. In some examples, the circuit structure layer may include a plurality of pixel circuits disposed in an array. Multiple pixel circuits disposed along the first direction X sequentially may be referred to as one row of pixel circuits, and multiple pixel circuits disposed along the second direction Y sequentially may be referred to as one column of pixel circuits. The first direction X may be perpendicular to the second direction Y. FIG. 10 illustrates pixel circuits in two rows and four columns, including, for example, an i-th row, an (i+1)-th row, a j-th column, a (j+1)-th column, a (j+2)-th column, and a (j+3)-th column, where i and j may be integers greater than 0. FIG. 11 illustrates schematically a cross-sectional view of a part taken along a direction Q-Q′ in FIG. 10.

In some examples, as shown in FIG. 10, in a direction parallel to the display substrate, a plurality of pixel circuits of the circuit structure layer may be divided into a plurality of pixel circuit groups, and each pixel circuit group may include two pixel circuits which are disposed adjacently along the first direction X. The two pixel circuits in each pixel circuit group may be symmetrically disposed with respect to a centerline of the pixel circuit group along the first direction X. Taking the pixel circuit group including the pixel circuit 30a located at the i-th row and the j-th column, and the pixel circuit 30b located at the i-th row and the (j+1)-th column as an example, the pixel circuits 30a and 30b in the pixel circuit group may be symmetrically disposed with respect to a first centerline O1. The two adjacent pixel circuit groups may be symmetrically disposed with respect to a second centerline of the two pixel circuit groups along the first direction X. For example, one pixel circuit group including pixel circuits 30a and 30b and a pixel circuit group adjacent to the right side may be symmetrically disposed with respect to a second centerline O2. In the present example, two pixel circuits in the pixel circuit group are symmetrically disposed, which may be beneficial to reducing the occupied space of the pixel circuit, thereby achieving a high-resolution display substrate.

In some examples, as shown in FIG. 11, in a direction perpendicular to the display substrate, the circuit structure layer may include: a first semiconductor layer 210, a first conductive layer 211, a second conductive layer 212, a second semiconductor layer 220, a third conductive layer 213, a fourth conductive layer 214, and a fifth conductive layer 215 that are sequentially disposed on the base substrate 200. In some examples, the first conductive layer 211 may also be referred to as a first gate metal layer, the second conductive layer 212 may also be referred to as a second gate metal layer, the third conductive layer 213 may also be referred to as a third gate metal layer, the fourth conductive layer 214 may also be referred to as a first source-drain metal layer, and the fifth conductive layer 215 may also be referred to as a second source-drain metal layer. In some examples, a light emitting structure layer and an encapsulation structure layer may be disposed on a side of the circuit structure layer away from the base substrate 200. The emitting structure layer may include a plurality of light emitting elements.

In some examples, as shown in FIG. 11, the circuit structure layer may further at least include a first insulation layer 201 to a sixth insulation layer 206. The first insulation layer 201 may be located between the first semiconductor layer 210 and the first conductive layer 211, the second insulation layer 202 may be located between the first conductive layer 211 and the second conductive layer 212, the third insulation layer 203 may be located between the second conductive layer 212 and the second semiconductor layer 220, the fourth insulation layer 204 may be located between the second semiconductor layer 220 and the third conductive layer 213, the fifth insulation layer 205 may be located between the third conductive layer 213 and the fourth conductive layer 214, and the sixth insulation layer 206 may be located between the fourth conductive layer 214 and the fifth conductive layer 215. In some examples, the first insulation layer 201 to the fifth insulation layer 205 may be inorganic insulation layers, and the sixth insulation layer 206 may be an organic insulation layer. However, the present embodiment is not limited thereto.

An exemplary description will be given for a structure and a manufacturing process of the display substrate below with reference to FIGS. 10 to 20. A “patterning process” mentioned in the embodiments of the present disclosure includes a treatment such as photoresist coating, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film which is made of a material on an underlying substrate by using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process.

“A and B are disposed in a same layer” and “A and B are of a same layer structure” in the present disclosure means that A and B are formed simultaneously through a same patterning process, or distances between surfaces of A and B close to a base substrate and the base substrate are substantially the same, or the surfaces of A and B close to the base substrate are in direct contact with a same film layer. A “thickness” of a film is a dimension of the film in a direction perpendicular to the display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B. The “shape of A” in the present disclosure refers to a shape of an orthographic projection of A on the base substrate.

The equivalent circuit of the pixel circuit of the circuit structure layer of this example may be shown in FIG. 4. The pixel circuit may include six first type of transistors and two second type of transistors. The transistor types of the first type of transistors and the second type of transistors may be different. For example, the first type of transistors may be low temperature polysilicon thin film transistors, and the second type of transistors may be oxide thin film transistors. In this example, the first transistors and the second transistors of the pixel circuit may be oxide thin film transistors and the third transistors to the eighth transistors may be low temperature polysilicon thin film transistors.

The structures of the pixel circuit 30a located at the i-th row and the j-th column, and the pixel circuit 30b located at the i-th row and the (j+1)-th column will be explained below as an example. Herein, the pixel circuit 30a may include a first transistor 31a, a second transistor 32a, a third transistor 33a, a fourth transistor 34a, a fifth transistor 35a, a sixth transistor 36a, a seventh transistor 37a, an eighth transistor 38a, a first capacitor 41a, and a second capacitor 42a. The pixel circuit 30b may include a first transistor 31b, a second transistor 32b, a third transistor 33b, a fourth transistor 34b, a fifth transistor 35b, a sixth transistor 36b, a seventh transistor 37b, an eighth transistor 38b, a first capacitor 41b, and a second capacitor 42b.

In some examples, the preparing process of the display substrate may include the following operations.
(1) A base substrate is provided. In some examples, the base substrate 200 may be a rigid substrate, or may be a flexible substrate. For example, the rigid substrate may include, but is not limited to, one or more of glass and quartz, and the flexible substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In some examples, the flexible base substrate may include a first flexible material layer, a first inorganic material layer, a semiconductor layer, a second flexible material layer and a second inorganic material layer which are stacked. Materials of the first flexible material layer and the second flexible material layer may be polyimide (PI), polyethylene terephthalate (PET) or a surface-treated polymer soft film, or the like; materials of the first inorganic material layer and the second inorganic material layer may be silicon nitride (SiNx, x>0) or silicon oxide (SiOy, y>0), etc., for improving the water-resistance and oxygen-resistance of the base substrate; and the material of the semiconductor layer may be amorphous silicon (a-si). The present embodiment is not limited thereto.
(2) A first semiconductor layer is formed. In some examples, a first semiconductor thin film is deposited on the base substrate, and the first semiconductor thin film is patterned through a patterning process to form the first semiconductor layer disposed on the base substrate. In some examples, a material of the first semiconductor layer may be amorphous silicon (a-Si), polycrystalline silicon (p-Si), hexathiophene or polythiophene, or other materials.

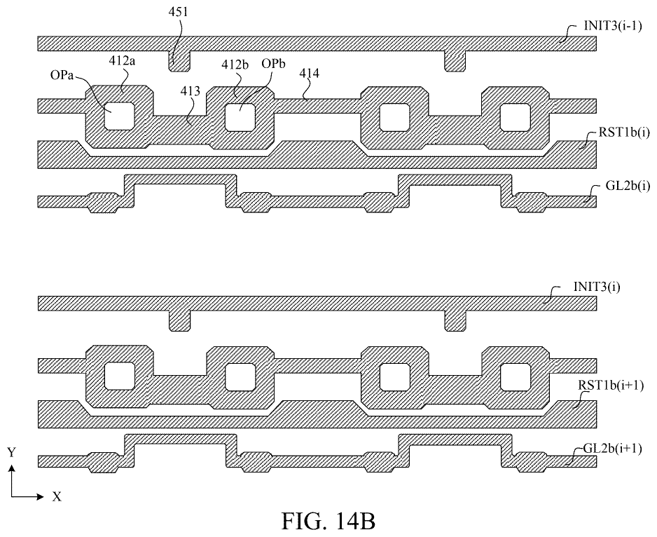

FIG. 12 is a schematic diagram of the display substrate after a first semiconductor layer is formed in FIG. 10. In some examples, as shown in FIG. 12, the first semiconductor layer of the display substrate may at least include active layers of a plurality of first type of transistors of a plurality of pixel circuits (which may include, for example, an active layer 330a of a third transistor, an active layer 340a of a fourth transistor, an active layer 350a of a fifth transistor, an active layer 360a of a sixth transistor, an active layer 370a of a seventh transistor, and an active layer 380a of an eighth transistor of the pixel circuit of the i-th row and the j-th column, an active layer 330b of the third transistor, an active layer 340b of a fourth transistor, an active layer 350b of a fifth transistor, an active layer 360b of a sixth transistor, an active layer 370b of a seventh transistor and an active layer 380b of an eighth transistor of the pixel circuit of the i-th row and the (j+1)-th column, an active layer 380a′ of an eighth transistor of the pixel circuit of the (i−1)-th row and the j-th column, and an active layer 380b′ of an eighth transistor of the pixel circuit of the (i−1)-th row and the (j+1)-th column). In some examples, the active layer of each first type of transistor of the pixel circuit may include: at least one channel region and a first region and a second region located on opposite sides of the channel region.

In some examples, as shown in FIG. 12, in the pixel circuit of the i-th row and the j-th column, the active layer 370a of the seventh transistor is located on a side of the active layer 330a of the third transistor in the second direction Y, the active layer 360a of the sixth transistor and the active layer 380a of the eighth transistor are located on a side of the active layer 330a of the third transistor in an opposite direction of the second direction Y, the active layer 340a of the fourth transistor is located on a side of the active layer 330a of the third transistor in an opposite direction of the first direction X, and the active layer 350a of the fifth transistor is located on a side of the active layer 330a of the third transistor in the first direction X. The active layer 380a′ of the eighth transistor of the pixel circuit of the (i−1)-th row and the j-th column may be located on a side of the active layer 370a of the seventh transistor of the pixel circuit of the i-th row and the j-th column in the first direction X, and is aligned with it in the first direction X. The active layer 380a of the eighth transistor of the pixel circuit of the i-th row and the j-th column may be aligned with the active layer of the seventh transistor of the pixel circuit of the (i+1)-th row and the j-th column in the first direction. The disposement mode in this example is beneficial to saving the occupied space of the pixel circuit.

In some examples, as shown in FIG. 12, a pattern of a first semiconductor layer of the pixel circuit of the i-th row and j-th column and a pattern of a first semiconductor layer of the pixel circuit of the i-th row and the (j+1)-th column may be substantially symmetrical with respect to the first centerline O1. The disposement mode in this example may be beneficial to sharing vias and traces subsequently, thereby facilitating the saving of the occupied space of the pixel circuit.

In some examples, as shown in FIG. 12, in the pixel circuit of the i-th row and the j-th column, the active layer 330a of the third transistor, the active layer 340a of the fourth transistor, and the active layer 350a of the fifth transistor may be of an integral structure connected to each other, and the active layer 360a of the sixth transistor and the active layer 380a of the eighth transistor may be of an integral structure connected to each other. A first region of the active layer 330a of the third transistor is directly connected to a second region of the active layer 350a of the fifth transistor, and a second region of the active layer 330a of the third transistor is directly connected to a second region of the active layer 340a of the fourth transistor. A second region of the active layer 360a of the sixth transistor is directly connected to a second region of the active layer 380a of the eighth transistor.

In some examples, a first region of the active layer 340a of the fourth transistor, a first region of the active layer 350a of the fifth transistor, a first region of the active layer 360a of the sixth transistor, a first region and a second region of the active layer 370a of the seventh transistor, and a first region of the active layer 380a of the eighth transistor may be independently disposed.

In some examples, as shown in FIG. 12, a shape of the active layer 330a of the third transistor may be substantially U-shaped; and shapes of active layer 340a of the fourth transistor, the active layer 350a of the fifth transistor, the active layer 360a of the sixth transistor, the active layer 370a of the seventh transistor, and the active layer 380a of the eighth transistor may be substantially I-shaped. The present embodiment is not limited thereto.
(3) A first conductive layer is formed. In some examples, a first insulation thin film and a first conductive thin film are deposited sequentially on the base substrate on which the aforementioned structure is formed, and the first conductive thin film is patterned through a patterning process to form a first insulation layer and a first conductive layer disposed on the first insulation layer. In some examples, the first insulation layer may also be referred to as a first gate insulation layer.

In some examples, after the first conductive layer is formed, the first conductive layer may be used as a shield to perform a conductive treatment on the first semiconductor layer. A region of the first semiconductor layer, which is shielded by the first conductive layer, forms channel regions of the plurality of first type of transistors, and a region of the first semiconductor layer, which is not shielded by the first conductive layer, is made to be conductive, that is, all of the first regions and the second regions of the active layers of the first type of transistors are made to be conductive.

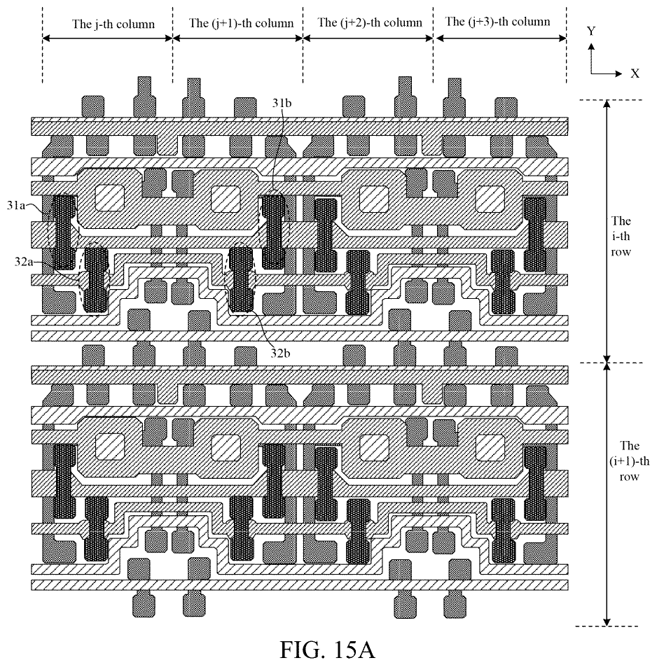

FIG. 13A is a schematic diagram of the display substrate after the first conductive layer is formed in FIG. 10. FIG. 13B is a schematic diagram of the first conductive layer in FIG. 13A. In some examples, as shown in FIGS. 13A and 13B, the first conductive layer of the display substrate may at least include first scan lines (e.g., first scan lines GL1 (i) and GL1 (i+1)), compensation control lines (e.g., compensation control lines GP (i) and GP (i+1)), first control lines (e.g., first control lines EML1 (i) and EML1 (i+1)), second control lines (e.g., second control lines EML2 (i) and EML2 (i+1)), and first electrode plates (e.g., first electrode plate 411a and 411b) of the first capacitors of the plurality of pixel circuits.

In some examples, a shape of the first electrode plate 411a of the first capacitor of the pixel circuit of the i-th row and the j-th column may be substantially a rectangle, for example, a rounded rectangle. An overlapping portion between the first electrode plate 411a of the first capacitor and the active layer 330a of the third transistor 33a may serve as a gate electrode of the third transistor 33a. A shape of the first electrode plate 411b of the first capacitor of the pixel circuit of the i-th row and the (j+1)-th column may be substantially a rectangle, for example, a rounded rectangle. An overlapping portion between the first electrode plate 411b of the first capacitor and the active layer 330b of the third transistor 33b may serve as a gate electrode of the third transistor 33b. The first electrode plates 411a and 411b may be substantially symmetrical with respect to the first centerline O1.

In some examples, the first scan line GL1 (i) may be substantially in a shape of a straight line extending along the first direction X. The first scan line GL1 (i) may be located on a side of the first electrode plates 411a and 411b in the second direction Y. An overlapping portion between the first scan line GL1 (i) and the active layer 340a of the fourth transistor 34a of the pixel circuit of the i-th row and j-th column may serve as a gate electrode of the fourth transistor 34a, and an overlapping portion between the first scan line GL1 (i) and the active layer 340b of the fourth transistor 34b of the pixel circuit of the i-th row and (j+1)-th column may serve as a gate electrode of the fourth transistor 34b. In the first direction X, the first scan line GL1 (i) may include a first overlapping portion between the first scan line GL1 (i) and the active layer 340a of the fourth transistor 34a, a second overlapping portion between the first scan line GL1 (i) and the active layer 340b of the fourth transistor 34b, and an extension portion connected between the first overlapping portion and the second overlapping portion. A length of the first overlapping portion and a length of the second overlapping portion along the second direction Y may be substantially the same, and a length of the first overlapping portion along the second direction Y may be greater than a length of the extending portion along the second direction Y. The disposement mode in the present example may be beneficial to ensuring a performance of the fourth transistor and avoiding overlapping of the first scan line with patterns of the remaining first semiconductor layers.

In some examples, the compensation control lines GP (i) and GP (i+1) may approximately have a straight line shape extending along the first direction X. The compensation control line GP (i) may be located on a side of the first scan line GL1 (i) in the second direction Y, and the compensation control line GP (i+1) may be located between the first scan line GL1 (i+1) and the second control line EML2 (i) and is located on a side of the second control line EML2 (i) in an opposite direction of the second direction Y. An overlapping portion between the compensation control line GP (i) and the active layer 370a of the seventh transistor 37a of the pixel circuit of the i-th row and the j-th column may serve as a gate of the seventh transistor 37a, and an overlapping portion between the compensation control line GP (i) and the active layer 380a′ of the eighth transistor 38a′ of the pixel circuit of the (i−1)th row and the j-th column may serve as a gate of the eighth transistor 38a′, an overlapping portion between the compensation control line GP (i) and the active layer 370b of the seventh transistor 37b of the pixel circuit of the i-th row and (j+1)-th column may serve as a gate of the seventh transistor 37b, and an overlapping portion between the compensation control line GP (i) and the active layer 380b′ of the eighth transistor 38b′ of the pixel circuit of the (i−1)-th row and the (j+1)-th column may serve as a gate of the eighth transistor 38b′. An overlapping portion between the compensation control line GP (i+1) and the active layer 380a of the eighth transistor 38a of the pixel circuit of the i-th row and the j-th column may serve as a gate of the eighth transistor 38a, and an overlapping portion between the compensation control line GP (i+1) and the active layer of the seventh transistor of the pixel circuit of the (i+1)-th row and the j-th column may serve as a gate of the seventh transistor, an overlapping portion between the compensation control line GP (i+1) and the active layer 380b of the eighth transistor 38b of the pixel circuit of the i-th row and (j+1)-th column may serve as a gate of the eighth transistor 38b, and an overlapping portion between the compensation control line GP (i+1) and the active layer of the seventh transistor of the pixel circuit of the (i+1)-th row and the (j+1)-th column may serve as a gate of the seventh transistor 38b′. In this example, the second reset control line connected to the gates of the eighth transistors of the pixel circuits of the present row and the compensation control line connected to the gates of the seventh transistors of the pixel circuits of the next row may be of an integral structure connected to each other.

In some examples, a shape of the first control line EML1(i) may be substantially a polyline shape extending along the first direction X. The first control line EML1 (i) may be located on a side of the first electrode plates 411a and 411b in an opposite direction of the second direction Y. The first control line EML1 (i) may be bent along the second direction Y. An overlapping portion between the first control line EML1 (i) and the active layer 350a of the fifth transistor 35a of the pixel circuit of the i-th row and j-th column may serve as a gate electrode of the fifth transistor 35a, and an overlapping portion between the first scan line GL1 (i) and the active layer 350b of the fifth transistor 35b of the pixel circuit of the i-th row and (j+1)-th column may serve as a gate electrode of the fifth transistor 35b.

In some examples, a shape of the second control line EML2(i) may be substantially a straight line shape extending along the first direction X. The second control line EML2 (i) may be located on a side of the first control line EML1 (i) in an opposite direction of the second direction Y. An overlapping portion between the second control line EML2 (i) and the active layer 360a of the sixth transistor 36a of the pixel circuit of the i-th row and j-th column may serve as a gate electrode of the sixth transistor 36a, and an overlapping portion between the second control line EML2 (i) and the active layer 360b of the sixth transistor 36b of the pixel circuit of the i-th row and (j+1)-th column may serve as a gate electrode of the sixth transistor 36b.
(4) A second conductive layer is formed. In some examples, a second insulation thin film and a second conductive thin film are deposited sequentially on the base substrate on which the aforementioned structures are formed, and the second conductive thin film is patterned through a patterning process to form a second insulation layer and a second conductive layer disposed on the second insulation layer. In some examples, the second insulation layer may also be referred to as a second gate insulation layer.

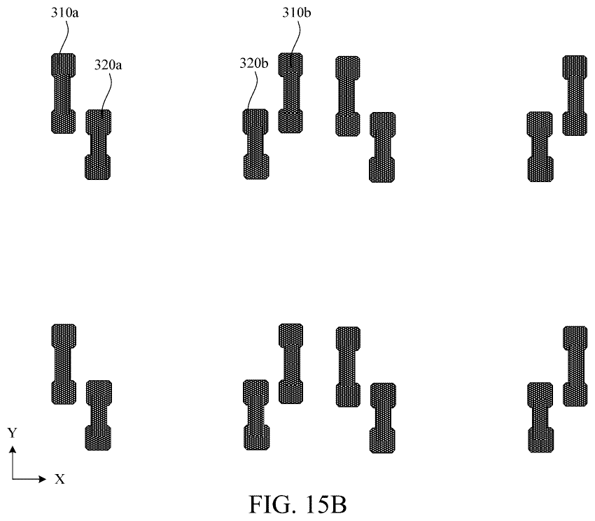

FIG. 14A is a schematic diagram of the display substrate after a second conductive layer is formed in FIG. 10. FIG. 14B is a schematic diagram of the second conductive layer in FIG. 14A. In some examples, as shown in FIGS. 14A and 14B, the second conductive layer of the display substrate may at least include third initial signal lines (e.g., third initial signal lines INIT3 (i−1) and INIT3 (i)), first auxiliary line (e.g., RST1b (i) and RST1b (i+1)), second auxiliary line (e.g., GL2b (i) and GL2b (i+1)), and second electrode plates (e.g., second electrode plates 412a and 412b) of the first capacitors of the plurality of pixel circuits.

In some examples, an orthographic projection of the second electrode plate 412a of the first capacitor of the pixel circuit of the i-th row and the j-th column on the base substrate may be partially overlapped with an orthographic projection of the first electrode plate 411a of the first capacitor of the pixel circuit of the i-th row and the j-th column on the base substrate. The orthographic projection of the second electrode plate 412a on the base substrate may cover, for example, an orthographic projection of an edge of the first electrode plate 411a on the base substrate. The second electrode plate 412a may have a hollow region OPa, and an orthographic projection of the hollow region OPa on the base substrate may be substantially a rectangle, for example, a rounded rectangle. The orthographic projection of the second electrode plate 412a on the base substrate may be substantially a rectangular ring. The orthographic projection of the hollow region OPa on the base substrate may be located within a range of the orthographic projection range of the first electrode plate 411a on the base substrate. The second electrode plate 412b of the first capacitor of the pixel circuit of the i-th row and the (j+1)-th column may have a hollow region OPb, an orthographic projection of the hollow region OPb on the base substrate may be located within a range of an orthographic projection of the first electrode plate 411b on the base substrate, the orthographic projection of the second electrode plate 412b on the base substrate is partially overlapped with the orthographic projection portion of the first electrode plate 411b on the base substrate, for example, the orthographic projection of the second electrode plate 412b on the base substrate may cover an orthographic projection of an edge of the first electrode plate 411a on the base substrate.

In some examples, adjacent second electrode plates 412a and 412b in the same pixel circuit group may be connected through a first electrode plate connection block 413, and adjacent second electrode plates 412a and 412b in different pixel circuit groups may be connected through a second electrode plate connection block 414. Shapes of the first electrode plate connection blocks 413 and the second electrode plate connection blocks 414 may be substantially strip shapes extending along the first direction X. Herein, a length of the first electrode plate connection block 413 in the first direction X may be less than a length of the second electrode plate connection block 414 in the first direction X. A length of the first electrode plate connection block 413 in the second direction Y may be greater than a length of the second electrode plate connection block 414 in the second direction Y. The second electrode plate 412b has an upper edge and a lower edge in the second direction Y, and a distance between the first electrode plate connection block 413 and the lower edge of the second electrode plate 412b may be less than a distance between the first electrode plate connection block 413 and the upper edge of the second electrode plate 412b; and a distance between the second electrode plate connection block 414 and the lower edge of the second electrode plate 412b may be greater than a distance between the second electrode plate connection block 414 and the upper edge of the second electrode plate 412b. In the present example, adjacent second electrode plates 412a and 412b in the first direction X, the first electrode plate connection block 413 and the second electrode plate connection block 414 may be of an integral structure connected to each other.

In some examples, a shape of the third initial signal line INIT3(i−1) may be substantially a straight line shape extending along the first direction X. The third initial signal line INIT3 (i) may be located on a side of the second electrode plates 412a and 412b in the second direction Y. An orthographic projection of the third initial signal line INIT3 (i−1) on the base substrate may be at least partially overlapped with an orthographic projection of the compensation control line GP (i) on the base substrate located in the first conductive layer.

In some examples, a first protrusion portion 451 may be provided on a side of the third initial signal line INIT3 (i−1) close to the first electrode plate connection block 413, and the first protrusion portion 451 may be provided within each pixel circuit group. For example, an orthographic projection of the first protrusion portion 451 on the base substrate may be located between the active layer 380a′ of the eighth transistor 38a′ and the active layer 380b′ of the eighth transistor 38b′. The first protrusion portion 451 may be configured to be connected to a first region of the active layer 380a′ of the eighth transistor 38a′ and a first region of the active layer 380b′ of the eighth transistor 38b′ through the eighth connection electrode 508 formed subsequently. In some examples, the third initial signal line INIT3 (i−1) and a plurality of first projection portions 451 may be of an integral structure connected to each other.

In some examples, the first auxiliary line RST1b (i) may be located on a side of the second electrode plates 412a and 412b in an opposite direction of the second direction Y. A shape of the first auxiliary line RST1b (i) may be a straight line shape with unequal width extending along the first direction X.

In some examples, the second auxiliary line GL2b (i) may be located on a side of the first auxiliary line RST1b (i) in an opposite direction of the second direction Y, and is located on a side of the first control line EML1 (i) in the second direction Y. A shape of the second auxiliary line GL2b (i) may be substantially a polygonal line shape extending along the first direction X.
(5) A second semiconductor layer is formed. In some examples, a third insulation thin film and a second semiconductor thin film are sequentially deposited on the base substrate on which the aforementioned structures are formed, and the second semiconductor thin film is patterned through a patterning process to form a third insulation layer and a second semiconductor layer disposed on the third insulation layer. In some examples, a material of the second semiconductor layer may include indium gallium zinc oxide (IGZO). In some examples, the third insulation layer may also be referred to as a third gate insulation layer.

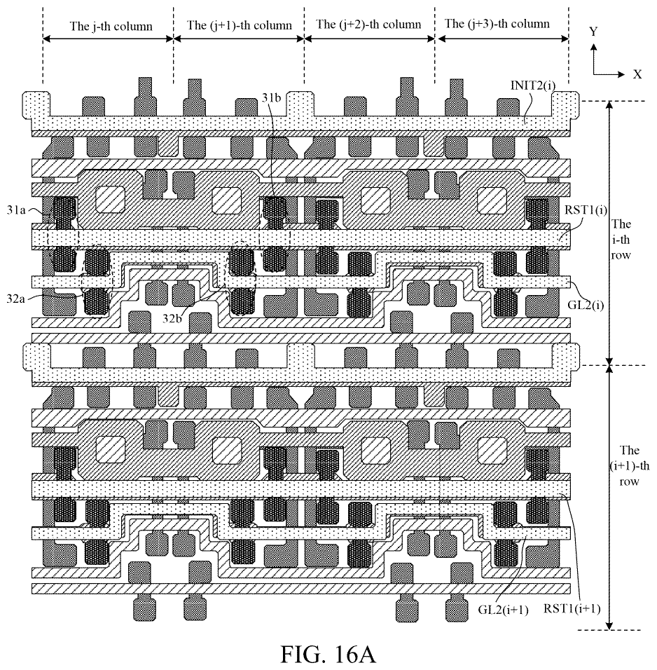

FIG. 15A is a schematic diagram of a display substrate after a second semiconductor layer is formed in FIG. 10. FIG. 15B is a schematic diagram of the second semiconductor layer in FIG. 15A. In some examples, as shown in FIGS. 15A and 15B, the second semiconductor layer of the display substrate may at least include active layers of a second type of transistors of a plurality of pixel circuits (for example, including an active layer 310a of the first transistor 31a and an active layer 320a of the second transistor 32a of the pixel circuit of the i-th row and the j-th column, and an active layer 310b of the first transistor 31b and an active layer 320b of the second transistor 32b of the pixel circuit of the i-th row and the (j+1)-th column).

In some examples, an orthographic projection of the active layer 310a of the first transistor 31a on the base substrate may be located on a side of the active layer 340a of the fourth transistor 34a close to the active layer 330a of the third transistor 33a, the active layer 320a of the second transistor 32a may be located on a side of the active layer 310a of the first transistor 31a in the first direction X, and the active layer 310a of the first transistor 31a and the active layer 320a of the second transistor 32a are arranged in a staggered manner in the first direction X. For example, the active layer 310a of the first transistor 31a may include a first end (i.e., a first region) and a second end (i.e., a second region) located on a side of the first end in the second direction Y, the active layer 320a of the second transistor 32a may include a first end (i.e., a first region) and a second end (i.e., a second region) located on a side of the first end in the second direction Y, and the first end of the active layer 310a of the first transistor 31a may be aligned with the second end of the active layer 320a of the second transistor 32a in the first direction X.

In some examples, orthographic projections of the active layer 310a of the first transistor 31a and the active layer 320a of the second transistor 32a on the base substrate may be substantially I-shaped.

In some examples, a pattern of the second semiconductor layer of the pixel circuit of the i-th row and the j-th column and a pattern of the second semiconductor layer of the pixel circuit of the i-th row and the j-th column may be symmetrically disposed with respect to the first centerline O1, so a pattern of the second semiconductor layer of the pixel circuit of the i-th row and the (j+1)-th column will not be described here.

In some examples, an overlapping portion between the first auxiliary line RST1b (i) and the active layer 310a of the first transistor 31a may serve as a bottom gate of the first transistor 31a, and an overlapping portion between the first auxiliary line RST1b (i) and the active layer 310b of the first transistor 31b may serve as a bottom gate of the first transistor 31b. Widths (i.e., a length along the second direction Y) of the overlapping portion between the first auxiliary line RST1b (i) and the active layer 310a of the first transistor 31a and the overlapping portion between the first auxiliary line RST1b (i) and the active layer 310b of the first transistor 31b may be greater than widths of the remaining parts of the first auxiliary line RST1b (i). A disposement mode in the present example is beneficial to ensuring that the first auxiliary line shades a channel region of the active layer of the first transistor, so as to avoid affecting a performance of the first transistor.

In some examples, an overlapping portion between the second auxiliary line GL2b (i) and the active layer 320a of the second transistor 32a may serve as a bottom gate of the second transistor 32a, and an overlapping portion between the second auxiliary line GL2b (i) and the active layer 320b of the second transistor 32b may serve as a bottom gate of the second transistor 32b. Widths (i.e., a length along the second direction Y) of the overlapping portion between the second auxiliary line GL2b (i) and the active layer 320a of the second transistor 32a and the overlapping portion between the first auxiliary line GL2b (i) and the active layer 320b of the second transistor 32b may be greater than widths of the remaining parts of the second auxiliary line RST1b (i). A disposement mode in the present example is beneficial to ensuring that the second auxiliary line shades a channel region of the active layer of the second transistor, so as to avoid affecting a performance of the second transistor.
(6) A third conductive layer is formed. In some examples, a fourth insulation thin film and a third conductive thin film are sequentially deposited on the base substrate on which the aforementioned patterns are formed, and the third conductive thin film is patterned through a patterning process to form a fourth insulation layer and a third conductive layer disposed on the fourth insulation layer. In some examples, the fourth insulation layer may also be referred to as a fourth gate insulation layer.

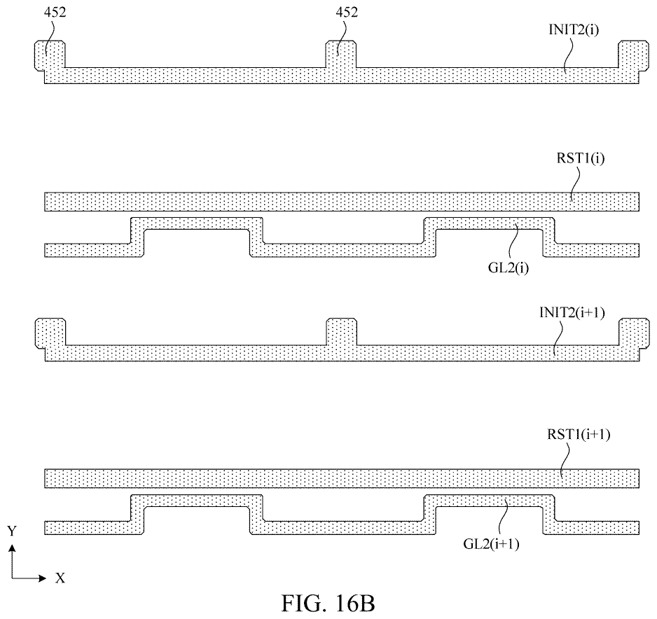

FIG. 16A is a schematic diagram of the display substrate after a third conductive layer is formed in FIG. 10. FIG. 16B is a schematic diagram of the third conductive layer in FIG. 16A. In some examples, as shown in FIGS. 16A and 16B, the third conductive layer of the display substrate may at least include second initial signal lines (e.g., second initial signal lines INIT2 (i) and INIT2 (i+1)), first reset control lines (e.g., RST1 (i) and RST1 (i+1)), and second scan lines (e.g., GL2 (i) and GL2 (i+1)).

In some examples, the second initial signal line INIT2 (i) may be located on a side of the first capacitor of the pixel circuit in the second direction Y. A shape of the second initial signal line INIT2(i) may be substantially a straight line shape extending along the first direction X. An orthographic projection of the second initial signal line INIT2 (i) on the base substrate may be at least partially overlapped with an orthographic projection of the third initial signal line INIT3 (i−1) located in the second conductive layer on the base substrate. In this example, the compensation control line, the third initial signal line and the second initial signal line are disposed to be stacked, so that the space occupied by the disposement of traces may be saved.

In some examples, a second protrusion portion 452 may be provided on a side of the second initial signal line INIT2 (i) away from the second electrode plate connection block 414. The second protrusion portion 452 may be provided at a junction position of two adjacent pixel circuit groups. For example, an orthographic projection of the second protrusion portion 452 on the base substrate may be located between the active layers of the seventh transistor of two adjacent pixel circuit groups. The second protrusion portion 452 may be configured to be connected to first regions of the active layers of the seventh transistors of the adjacent two pixel circuit groups through a first connection electrode 501 and an eleventh connection electrode 511 formed subsequently. In some examples, the second initial signal line INIT2 (i) and a plurality of second protrusion portions 452 may be of an integral structure connected to each other.

In some examples, the first reset control line RST1 (i) may be located on a side of the second electrode plates 412a and 412b in an opposite direction of the second direction Y. A shape of the first reset control line RST1 (i) may be substantially a straight line extending along the first direction X. An overlapping portion between the first reset control line RST1 (i) and the active layer 310a of the first transistor 31a may serve as a gate electrode of the first transistor 31a, and an overlapping portion between the first reset control line RST1 (i) and the active layer 310b of the first transistor 31b may serve as a gate electrode of the first transistor 31b. An orthographic projection of the first reset control line RST1 (i) on the base substrate may be at least partially overlapped with an orthographic projection of the first auxiliary line RST1b (i) on the base substrate, for example, the orthographic projection of the first auxiliary line RST1b (i) on the base substrate may cover the orthographic projection of the first reset control line RST1 (i) on the base substrate.

In some examples, the second scan line GL2 (i) may be located on a side of the first reset control line RST1 (i) in an opposite direction of the second direction Y. A shape of the second scan line GL2 (i) may be substantially a polygonal line shape extending along the first direction X. An overlapping portion between the second scan line GL2 (i) and the active layer 320a of the second transistor 32a may serve as a gate of the second transistor 32a, and an overlapping portion between the second scan line GL2b (i) and the active layer 320b of the second transistor 32b may serve as a gate of the second transistor 32b. An orthographic projection of the second scan line GL2 (i) on the base substrate may be at least partially overlapped with an orthographic projection of the second auxiliary line GL2b (i) on the base substrate, for example, the orthographic projection of the second auxiliary line GL2b (i) on the base substrate may cover the orthographic projection of the second scan line GL2 (i) on the base substrate.
(7) A fifth insulation layer is formed. In some examples, a fifth insulation thin film is deposited on the base substrate on which the aforementioned patterns are formed, and the fifth insulation thin film is patterned through a patterning process to form a fifth insulation layer. The fifth insulation layer may be provided with a first group of vias and a second group of vias. For example, a first group of vias are formed though a first patterning process, and a second group of vias are formed through a second patterning process. In some examples, the fifth insulation layer may also be referred to as an interlayer dielectric layer.

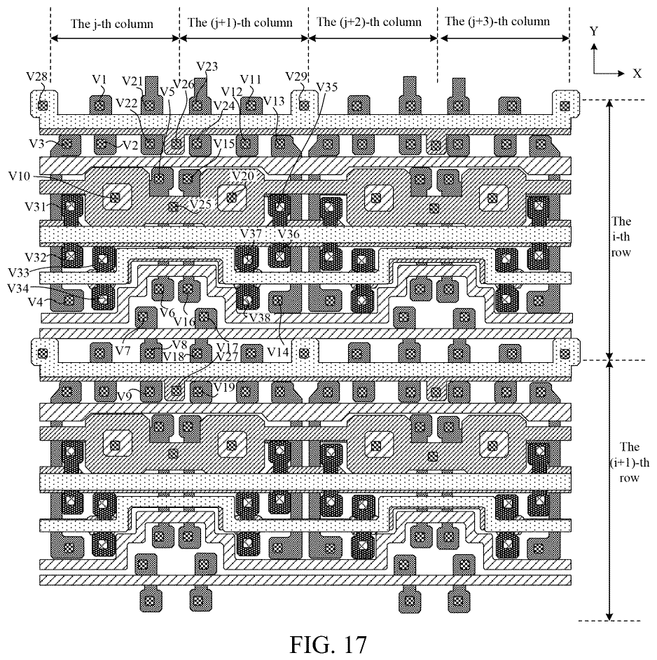

FIG. 17 is a schematic view of a display substrate after a fifth insulation layer is formed in FIG. 10. In some examples, as shown in FIG. 17, the first group of vias opened in the fifth insulation layer of the display substrate may include a plurality of first type of vias (including, for example, a first via to a ninth via V9, an eleventh via to a nineteenth via V19), a plurality of second type of vias (including, for example, a the tenth via V10 and a twentieth via V20), a plurality of third type of vias (including, for example, a twenty-fifth via V25 to a twenty-seventh via V27); and the second group of vias may at least include a plurality of fourth type of vias (including, for example, a twenty-eighth via V28 and a twenty-ninth via V29), and a plurality of fifth type of vias (including, for example, a thirty-first via V31 to a thirty-eighth via V38).

In some examples, a fifth insulation layer, a fourth insulation layer, a third insulation layer, a second insulation layer, and a first insulation layer within the first type of vias may be removed to expose part of a surface of the first semiconductor layer. A fifth insulation layer, a fourth insulation layer, a third insulation layer, and a second insulation layer within the second type of vias may be removed to expose part of a surface of the first conductive layer. A fifth insulation layer, a fourth insulation layer, and a third insulation layer within the third type of vias may be removed to expose part of a surface of the second conductive layer. A fifth insulation layer within the fourth type of vias may be removed to expose part of a surface of the third conductive layer. A fifth insulation layer and a fourth insulation layer within the fifth type of vias may be removed to expose part of a surface of the second semiconductor layer.
(8) A fourth conductive layer is formed. In some examples, a fourth conductive thin film is deposited on the base substrate on which the aforementioned patterns are formed, and the fourth insulation thin film is patterned through a patterning process to form a fourth conductive layer on the fifth insulation layer.

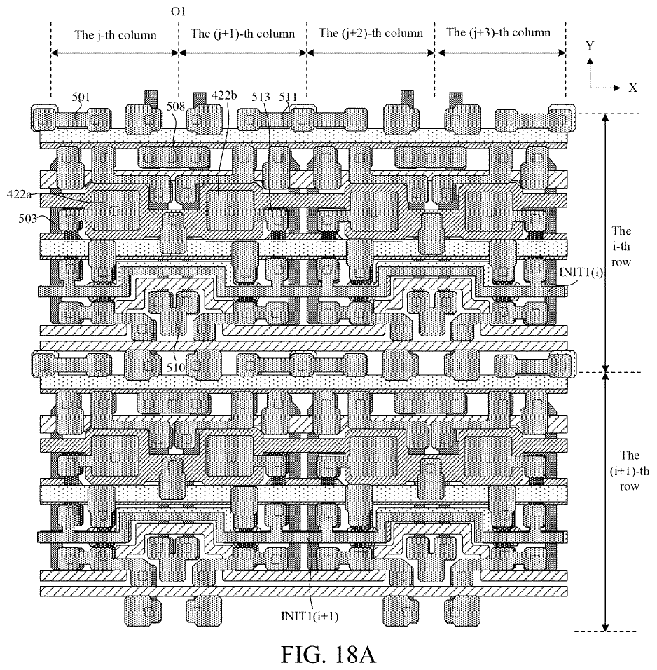

FIG. 18A is a schematic diagram of the display substrate after a fourth conductive layer is formed in FIG. 10. FIG. 18B is a schematic diagram of a fourth conductive layer in FIG. 18A. In some examples, as shown in FIGS. 18A and 18B, the fourth conductive layer of the display substrate may at least include first initial signal lines (e.g., INIT1 (i) and INIT1 (i+1)), fourth electrode plates of second capacitors of a plurality of pixel circuits (e.g., fourth electrode plates 422a and 422b), and a plurality of connection electrodes (e.g., including a first connection electrode 501 to a twentieth connection electrode 520).

In some examples, a shape of the first initial signal line INIT1(i) may be substantially a polyline shape extending along the first direction X. An orthographic projection of the first initial signal line INIT1 (i) on the base substrate is located on a side of an orthographic projection of the first control line EML1 (i) on the base substrate along the second direction Y. An orthographic projection of the first initial signal line INIT1 (i) on the base substrate is at least partially overlapped with an orthographic projection of the second scan line GL2 (i) located in the third conductive layer on the base substrate. In this example, the second auxiliary line, the second scan line and the first initial signal line are stacked, so that the space occupied by the disposement of traces may be saved.

In some examples, a third protrusion portion 453 may be provided on a side of the first initial signal line INIT1 (i) close to the second electrode plate connection block 414. The third protrusion portion 453 may be provided in each pixel circuit. For example, an orthographic projection of the third protrusion portion 453 on the base substrate may be adjacent to an orthographic projection of the active layer of the fourth transistor on the base substrate. One third protrusion portion 453 may be connected to a first region of the active layer 310a of the first transistor 31a through the thirty-fourth via V34, and another third protrusion portion 453 may be connected to a first region of the active layer 310b of the first transistor 31b through the thirty-eighth via V38. In some examples, the first initial signal line INIT1 (i) and a plurality of third protrusion portions 453 may be of an integral structure connected to each other.

In some examples, an orthographic projection of the fourth electrode plate 422a of the second capacitor 42a of the pixel circuit of the i-th row and the j-th column on the base substrate may be substantially rectangular. The orthographic projection of the fourth electrode plate 422a on the base substrate may be overlapped with orthographic projections of the first electrode plate 411a and the second electrode plate 412a of the first capacitor 41a on the base substrate. The orthographic projection of the fourth electrode plate 422a on the base substrate may cover an orthographic projection of the hollow region OPa on the base substrate, and the orthographic projection of the second electrode plate 412a on the base substrate may cover an orthographic projection of an edge of the fourth electrode plate 422a on the base substrate. The fourth electrode plate 422a may be connected to the first electrode plate 411a through the tenth via V10. An orthographic projection of the tenth via V10 on the base substrate may be located within a range of the orthographic projection of the hollow region OPa on the base substrate.

In some examples, an orthographic projection of the fourth electrode plate 422b of the second capacitor 42b of the pixel circuit of the i-th row and the (j+1)-th column on the base substrate may be substantially of a rectangle. The orthographic projection of the fourth electrode plate 422b on the base substrate may cover an orthographic projection of the hollow region OPb on the base substrate, and the orthographic projection of the second electrode plate 412b on the base substrate may cover an orthographic projection of an edge of the fourth electrode plate 422b on the base substrate. The fourth electrode plate 422b may be connected to the first electrode plate 411b through the twentieth via V20. An orthographic projection of the twentieth via V20 on the base substrate may be located within a range of the orthographic projection of the hollow region OPb on the base substrate.

In some examples, a shape of the first connection electrode 501 may be substantially a dumbbell shape extending along the first direction X. The first connection electrode 501 may be connected to a first region of the active layer 370a of the seventh transistor 37a through the first via V1, and may also be connected to the second protrusion portion 452 through the twenty-sixth via V26, thereby achieving that the seventh transistor 37a is electrically connected to the second initial signal line INIT2 (i). A shape of the eleventh connection electrode 511 may be substantially a dumbbell shape extending along the first direction X. The eleventh connection electrode 511 may be connected to a first region of the active layer 370b of the seventh transistor 37b through the eleventh via V11, and may also be connected to another second protrusion portion 452 through the twenty-seventh via V27, thereby achieving that the seventh transistor 37b is electrically connected to the second initial signal line INIT2 (i). The first connection electrode 501 and the eleventh connection electrode 511 of adjacent pixel circuit groups may be of an integral structure connected to each other.

In some examples, the second connection electrode 502 may be substantially of a rectangle. The second connection electrode 502 may be electrically connected to a first region of the active layer 340a of the fourth transistor 34a through the third via V3. The second connection electrode 502 may be configured to be connected to a data line DL (j) formed subsequently.

In some examples, a shape of the third connection electrode 503 may be substantially a rectangle. The third connection electrode 503 may be connected to a second region of the active layer 310a of the first transistor 31a through the thirty-first via V31. The third connection electrode 503 may be located on a side of the fourth electrode plate 422a in an opposite direction of the first direction X, and the third connection electrode 503 and the fourth electrode plate 422a may be of an integral structure connected to each other. The fourth electrode plate 422a may be electrically connected to the first transistor 31a through the third connection electrode 503.

In some examples, a shape of the fourth connection electrode 504 may be substantially a rectangle. The fourth connection electrode 504 may be located on a side of the first initial signal line INIT1 (i) in the second direction Y, and may be adjacent to the third protrusion portion 453 in the first direction X. The fourth connection electrode 504 may be connected to a second region of the active layer 320a of the second transistor 32a through the thirty-third via V33.

In some examples, a shape of the fifth connection electrode 505 may be substantially a polyline shape extending along the first direction X. The fifth connection electrode 505 may be located on a side of the first initial signal line INIT1 (i) in an opposite direction of the second direction Y. The fifth connection electrode 505 may be connected to a second region of the active layer 340a of the fourth transistor 34a through the fourth via V4, may also be connected to a first region of the active layer 320a of the second transistor 32a through the thirty-fourth via V34, and may also be connected to a first region of the active layer 360a of the sixth transistor 36a through the seventh via V7. The fifth connection electrode 505 can achieve an electrical connection between the third transistor 33a, the second transistor 32a, the fourth transistor 34a, and the sixth transistor 36a, and may serve as a third node N3 of the pixel circuit 30a.

In some examples, a shape of the sixth connection electrode 506 may be substantially a rectangle. The sixth connection electrode 506 may be located on a side of the fifth connection electrode 505 in an opposite direction of the second direction Y. The sixth connection electrode 506 may be connected to a second region of the active layer 360a of the sixth transistor 36a through the eighth via V8. The sixth connection electrode 506 may be configured to be electrically connected to a first anode connection electrode 523 formed subsequently.

In some examples, a shape of the seventh connection electrode 507 may be substantially a “z” shape. The seventh connection electrode 507 may be located on a side of the second connection electrode 502 in the first direction X. The seventh connection electrode 507 may be connected to a second region of the active layer 370a of the seventh transistor 37a through the second via V2, and may also be connected to a first region of the active layer 330a of the third transistor 33a through the fifth via V5. The seventh connection electrode 507 may achieve an electrical connection between the seventh transistor 37a, the third transistor 33a, and the fifth transistor 35a, and may serve as a second node N2 of the pixel circuit 30a.

In some examples, the eighth connection electrode 508 may be substantially symmetrical with respect to the first centerline O1. The eighth connection electrode 508 may be substantially in a strip shape extending along the first direction X. The eighth connection electrode 508 may be located between the seventh connection electrode 507 and the seventeenth connection electrode 517. The eighth connection electrode 508 may be connected to a first region of the active layer 380a′ of the eighth transistor 38a′ through the twenty-second via V22, may also be connected to a first region of the active layer 380b′ of the eighth transistor 38b′ through the twenty-fourth via V24, and may also be connected to the first protrusion portion 451 through the twenty-sixth via V26, thereby achieving an electrical connection between the eighth transistor 38a′, the eighth transistor 38b′ and the third initial signal line INIT3 (i−1).

In some examples, the ninth connection electrode 509 may be substantially symmetrical with respect to the first centerline O1. A shape of the ninth connection electrode 509 may be substantially a rectangle. The ninth connection electrode 509 may be located between the fourth electrode plates 422a and 422b. The ninth connection electrode 509 may be connected to the first electrode plate connection block 413 through the twenty-fifth via V25, thereby achieving an electrical connection to the second electrode plates 412a and 412b. The ninth connection electrode 509 may be configured to be connected to a first power supply line 61a formed subsequently.

In some examples, the tenth connection electrode 510 may be substantially symmetrical with respect to the first centerline O1. The tenth connection electrode 510 may be located between the fifth connection electrode 505 and the fifteenth connection electrode 515. A shape of the tenth connection electrode 510 may be substantially a Mickey avatar shape. The tenth connection electrode 510 may be connected to a first region of the active layer 350a of the fifth transistor 35a through the sixth via V6, and may also be connected to a first region of the active layer 350b of the fifth transistor 35b through the sixteenth via V16. The tenth connection electrode 510 may be configured to be connected to a first power supply line 61a formed subsequently.

In some examples, the twelfth connection electrode 512 and the second connection electrode 502 may be substantially symmetrical with respect to the first centerline O1. The twelfth connection electrode 512 may be substantially of a rectangle. The twelfth connection electrode 512 may be connected to a first region of the active layer 340b of the fourth transistor 34b through the thirteenth via V13. The twelfth connection electrode 512 may be configured to be connected to a data line DL (j+1) formed subsequently.

In some examples, the thirteenth connection electrode 513 and the third connection electrode 503 may be substantially symmetrical with respect to the first centerline O1. A shape of the thirteenth connection electrode 513 may be substantially a rectangle. The thirteenth connection electrode 513 may be connected to a second region of the active layer 310b of the first transistor 31b through the thirty-fifth via V35. The thirteenth connection electrode 513 may be located on a side of the fourth electrode plate 422b in the first direction X, and the thirteenth connection electrode 513 and the fourth electrode plate 422b may be of an integral structure connected to each other. The fourth electrode plate 422b may be electrically connected to the first transistor 31b through the thirteenth connection electrode 513.

In some examples, the fourteenth connection electrode 514 and the fourth connection electrode 504 may be substantially symmetrical with respect to the first centerline O1. The fourteenth connection electrode 514 may be substantially of a rectangle. The fourteenth connection electrode 514 may be located on a side of the first initial signal line INIT1 (i) in the second direction Y, and may be adjacent to the third protrusion portion 453 in the first direction X. The fourteenth connection electrode 514 may be electrically connected with a second region of the active layer 320b of the second transistor 32b through the thirty-seventh via V37.

In some examples, the fifteenth connection electrode 515 and the fifth connection electrode 505 may be substantially symmetrical with respect to the first centerline O1. A shape of the fifteenth connection electrode 515 may be substantially a polygonal line extending along the first direction X. The fifteenth connection electrode 515 may be located on a side of the first initial signal line INIT1 (i) in an opposite direction of the second direction Y. The fifteenth connection electrode 515 may be connected to a second region of the active layer 340b of the fourth transistor 34b through the fourteenth via V14, may also be connected to a first region of the active layer 320b of the second transistor 32b through the thirty-eighth via V38, and may also be connected to a first region of the active layer 360b of the sixth transistor 36b through the seventeenth via V17. The fifteenth connection electrode 515 may achieve an electrical connection between the third transistor 33b, the second transistor 32b, the fourth transistor 34b, and the sixth transistor 36b, and may serve as a third node N3 of the pixel circuit 30b.

In some examples, the sixteenth connection electrode 516 and the sixth connection electrode 506 may be substantially symmetrical with respect to the first centerline O1. The sixteenth connection electrode 516 may be substantially of a rectangle. The sixteenth connection electrode 516 may be located on a side of the fifteenth connection electrode 515 in an opposite direction of the second direction Y. The sixteenth connection electrode 516 may be connected to a second region of the active layer 360b of the sixth transistor 36b through the eighteenth via V18. The sixteenth connection electrode 516 may be configured to be electrically connected to a second anode connection electrode 524 formed subsequently.

In some examples, the seventeenth connection electrode 517 and the seventh connection electrode 507 may be substantially symmetrical with respect to the first centerline O1. A shape of the seventeenth connection electrode 517 may be substantially a “z” shape. The seventeenth connection electrode 517 may be located on a side of the twelfth connection electrode 512 in an opposite direction of the first direction X. The seventeenth connection electrode 517 may be connected to a second region of the active layer 370b of the seventh transistor 37b through the twelfth via V12, and may also be connected to a first region of the active layer 330b of the third transistor 33b through the fifteenth via V15. The seventeenth connection electrode 517 may achieve an electrical connection between the seventh transistor 37b, the third transistor 33b, and the fifth transistor 35b, and may serve as a second node N2 of the pixel circuit 30b.

In some examples, the eighteenth connection electrode 518 may be substantially symmetrical with respect to the first centerline O1. The eighteenth connection electrode 518 may be substantially of a strip shape extending along the first direction X. The eighteenth connection electrode 518 may be located on a side of the sixth connection electrode 506 and the sixteenth connection electrode 516 in an opposite direction of the second direction Y. The eighteenth connection electrode 518 may be connected to a first region of the active layer 380a of the eighth transistor 38a through the ninth via V9, may also be connected to a first region of the active layer 380b of the eighth transistor 38b through the nineteenth via V19, and may also be connected to one first protrusion portion 451 through the twenty-seventh via V27, thereby achieving an electrical connection between the eighth transistor 38a, the eighth transistor 38b and the third initial signal line INIT3 (i).

In some examples, the nineteenth connection electrode 519 and the twentieth connection electrode 520 may be located on a side of the eighth connection electrode 508 in the second direction Y. The nineteenth connection electrode 519 may be substantially of a rectangle. The nineteenth connection electrode 519 may be connected to a second region of the active layer 380a′ of the eighth transistor 38a′ through the twenty-first via V21. The twentieth connection electrode 520 may be substantially of a rectangle. The twentieth connection electrode 520 may be connected to a second region of the active layer 380b′ of the eighth transistor 38b′ through the twenty-third via V23.
(9) A sixth insulation layer is formed. In some examples, a sixth insulation thin film is coated on the base substrate on which the aforementioned patterns are formed, and the sixth insulation thin film is patterned through a patterning process to form a sixth insulation layer. In some examples, the sixth insulation layer may also be referred to as a first planarization layer.

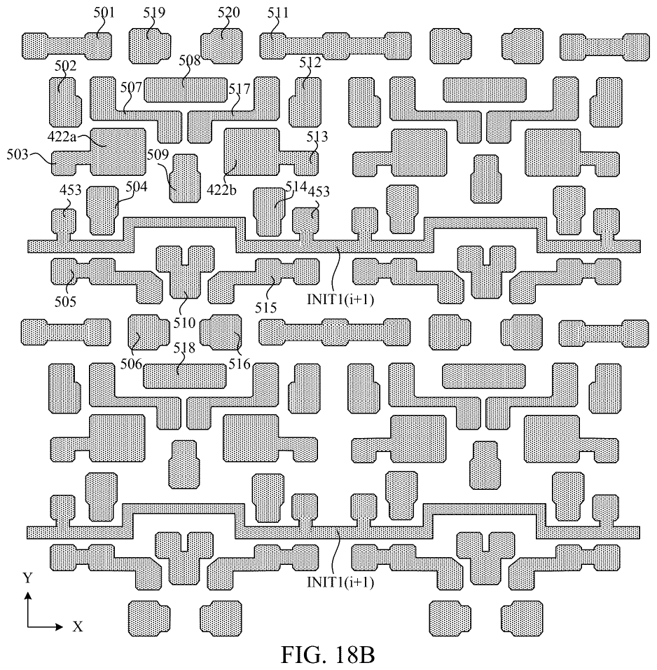

FIG. 19 is a schematic view of a display substrate after a sixth insulation layer is formed in FIG. 10. In some examples, as shown in FIG. 19, the sixth insulation layer of the display substrate may be provided with a plurality of vias, which may include, for example, a forty-first via V41 to a forty-fifth via V45, and a fifty-first via V51 to a fifty-third via V53. The sixth insulation layer within the forty-first via V41 to the forty-fifth via V45 and the fifty-first via V51 to the fifty-third via V53 may be removed to expose part of a surface of the fourth conductive layer.
(10) A fifth conductive layer is formed. In some examples, a fifth conductive thin film is deposited on the base on which the aforementioned patterns are formed, and the fifth conductive thin film is patterned through a patterning process to form a fifth conductive layer on the sixth insulation layer.

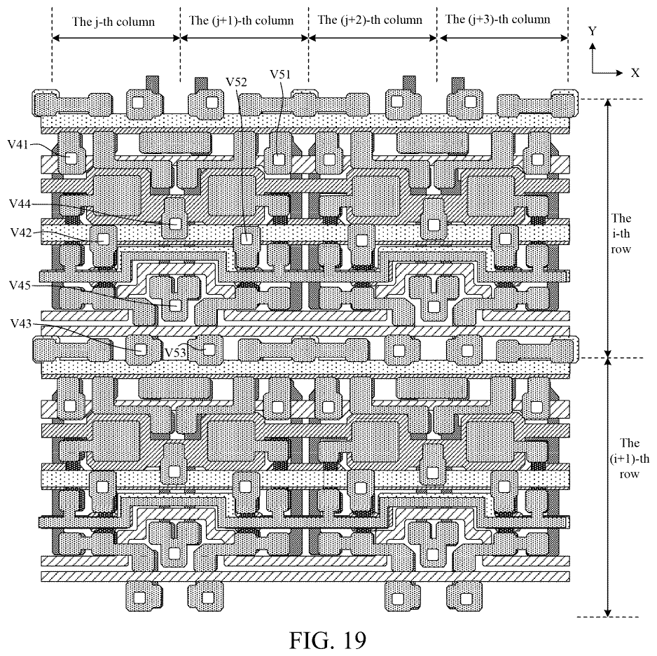

FIG. 20 is a schematic diagram of a fifth conductive layer in FIG. 10. In some examples, as shown in FIGS. 10 and 20, the fifth conductive layer of the display substrate may at least include a plurality of data lines (e.g., including data lines DL (j), DL (j+1), DL (j+2), and DL (j+3)), a plurality of first power supply lines (e.g., including first power supply lines 61a and 61b), third electrode plates of second capacitors of a plurality of the pixel circuits (e.g., including a third electrode plate 421a of the second capacitor 42a, a third electrode plate 421b of the second capacitor 42b), and a plurality of connection electrodes (e.g., including a twenty-first connection electrode 521, a twenty-second connection electrode 522, a first anode connection electrode 523, and a second anode connection electrode 524).

In some examples, the plurality of data lines and the plurality of first power supply lines may all extend along the second direction Y. The first power supply line to which one pixel circuit group is connected may be located between two data lines. For example, the first power supply line 61a may be located between the data lines DL (j) and DL (j+1), and the first power supply line 61b may be located between the data lines DL (j+2) and DL (j+3). The first power supply line 61a may be located on the first centerline O1, for example, may be substantially symmetrical with respect to the first centerline O1.

In some examples, the data lines DL (j) and DL (j+1) may be substantially lines extending along the second direction Y. The data line DL (j) may be connected to the second connection electrode 502 through the forty-first via V41, thereby achieving an electrical connection to the fourth transistor 34a. The data line DL (j+1) may be connected to the twelfth connection electrode 512 through the fifty-first via V51, thereby achieving an electrical connection to the fourth transistor 34b.

In some examples, a shape of the first power supply line 61a may be substantially a line shape extending along the second direction Y. On the one hand, the first power supply line 61a may be connected to the ninth connection electrode 509 through the forty-fourth via V44 to achieve an electrical connection to the second electrode plates 412a and 412b of the first capacitor 41a, and on the other hand, the first power supply line 61a may be connected to the tenth connection electrode 510 through the forty-fifth via V45. Since the tenth connection electrode 510 is electrically connected to a first region of the active layer of the fifth transistor 35a and a first region of the active layer of the fifth transistor 35b through a via, thereby achieving that the first power supply line 61a writes a first voltage signal to the first electrode of the fifth transistor 35a and the first electrode of the fifth transistor 35b.

In some examples, a first power supply protrusion block 61-1 may be provided on a side of the first power supply line 61a close to the data line DL (j), and a second power supply protrusion block 61-2 may be provided on a side of the first power supply line 61a close to the data line DL (j+1). The first power supply protrusion block 61-1 and the second power supply protrusion block 61-2 may be substantially symmetrical with respect to the first centerline O1. A first end of the first power supply protrusion block 61-1 is connected to the first power supply line 61a, and a second end of the first power supply protrusion block 61-1 extends in a direction towards the data line DL (j); and a first end of the second power supply protrusion block 61-2 is connected to the first power supply line 61a, and a second end of the second power supply protrusion block 61-2 extends in a direction towards the data line DL (j+1). Orthographic projections of the first power supply protrusion block 61-1 and the second power supply protrusion block 61-2 on the base substrate may be substantially trapezoidal. An orthographic projection of the first power supply protrusion block 61-1 on the base substrate may be at least partially overlapped with an orthographic projection of the fifth transistor 35a on the base substrate; and an orthographic projection of the second power supply protrusion block 61-2 on the base substrate may be at least partially overlapped with an orthographic projection of the fifth transistor 35b on the base substrate.

In some examples, the first power supply line 61a, and the plurality of first power supply protrusion blocks 61-1 and the plurality of second power supply protrusion blocks 61-2 may be of an integral structure connected to each other. In this example, the first power supply protrusion block and the second power supply protrusion block are provided, which is beneficial to improving a flatness of a whole surface of the fifth conductive layer. Moreover, by using the first power supply protrusion block and the second power supply protrusion block, not only a layout of the pixel structure may be facilitated, but also a parasitic capacitance between the first power supply line and the data line may be reduced.

In some examples, the orthographic projection of the third electrode plate 421a of the second capacitor 42a on the base substrate may be substantially of a rectangle. The third electrode plate 421a may be located between the data line DL (j) and the first power supply line 61a. The orthographic projection of the third electrode plate 421a on the base substrate may be at least partially overlapped with an orthographic projection of the fourth electrode plate 422a on the base substrate, for example, the orthographic projection of the third electrode plate 421a on the base substrate may cover the orthographic projection of the fourth electrode plate 422a on the base substrate.

In some examples, the third electrode plate 421b of the second capacitor 42b and the third electrode plate 421a of the second capacitor 42a may be substantially symmetrical with respect to the first centerline O1. The orthographic projection of the third electrode plate 421b of the second capacitor 42b on the base substrate may be substantially of a rectangle. The third electrode plate 421b may be located between the data line DL (j+1) and the first power supply line 61a. The orthographic projection of the third electrode plate 421b on the base substrate may be at least partially overlapped with an orthographic projection of the fourth electrode plate 422b on the base substrate, for example, the orthographic projection of the third electrode plate 421b on the base substrate may cover the orthographic projection of the fourth electrode plate 422b on the base substrate.

In some examples, the twenty-first connection electrode 521 may be located on a side of the third electrode plate 421a in an opposite direction of the second direction Y, and may be located between the data line DL (j) and the first power supply protrusion block 61-1 in the first direction X. The twenty-first connection electrode block 521 may be connected to the fourth connection electrode 504 through the forty-second via V42. The twenty-first connection electrode 521 and the third electrode plate 421a may be of an integral structure connected to each other. Since the fourth connection electrode 504 is connected to a second region of the active layer of the second transistor 32a through a via, and the twenty-second connection electrode 521 and the third electrode plate 421a are of an integral structure connected to each other, thus achieving that the third electrode plate 421a of the second capacitor 42a is electrically connected to the second electrode of the second transistor 32a.

In some examples, the twelfth connection electrode 522 may be located on a side of the third electrode plate 421b in an opposite direction of the second direction Y, and may be located between the data line DL (j+1) and the second power supply protrusion block 61-2 in the first direction X. The twenty-second connection electrode 522 may be connected to the fourteenth connection electrode 514 through the fifty-second via V52. The twenty-second connection electrode 522 and the third electrode plate 421b may be of an integral structure connected to each other. Since the fourteenth connection electrode 514 is connected to a second region of the active layer of the second transistor 32b through a via, and the twenty-second connection electrode 522 and the third electrode plate 421b are of an integral structure connected to each other, thus achieving that the third electrode plate 421b of the second capacitor 42b is electrically connected to the second electrode of the second transistor 32b.

In some examples, a shape of the first anode connection electrode 523 may be substantially a rectangle. The first anode connection electrode 523 may be connected to the sixth connection electrode 506 through the forty-third via V43 to achieve a connection to a second region of the active layer of the sixth transistor 36a. The first anode connection electrode 523 may be electrically connected to an anode of a light emitting element formed subsequently and located in the anode layer.

In some examples, a shape of the second anode connection electrode 524 may be substantially a rectangle. The second anode connection electrode 524 may be connected to the sixteenth connection electrode 516 through the fifty-third via V53 to achieve a connection to a second region of the active layer of the sixth transistor 36b. The second anode connection electrode 524 may be electrically connected to an anode of a light emitting element formed subsequently and located in the anode layer.

So far, the preparation of the circuit structure layer of this example has been completed on the base substrate. In some examples, in the prepared circuit structure layer which has been completed, a light emitting structure layer and an encapsulation structure layer may be prepared sequentially in the circuit structure layer. For example, the light emitting structure layer may include an anode layer, a pixel definition layer, an organic light emitting layer, and a cathode layer.

In some examples, a seventh insulation thin film is coated on the base substrate on which the aforementioned pattern are formed, and the seventh insulation thin film is patterned through a patterning process to form a seventh insulation layer (which may also be referred as a second planarization layer). Subsequently, an anode thin film is deposited on the base substrate on which the aforementioned patterns are formed, and the anode thin film is patterned through a patterning process to form an anode layer. Then, a pixel definition thin film is coated and a pixel definition layer is formed by masking, exposure and development processes. The pixel definition layer may be formed with a plurality of pixel openings exposing the anode layer. An organic emitting layer is formed in the pixel openings formed earlier, and the organic light emitting layer is connected with the anode layer. Subsequently, a cathode thin film is deposited, the cathode thin film is patterned through a patterning process to form a cathode layer, and the cathode layer is connected with the organic emitting layer. Then, the encapsulation structure layer is formed on the cathode layer, for example, the encapsulation structure layer may include a stacked structure of an inorganic material/an organic material/an inorganic material.

In some examples, the first conductive layer, the second conductive layer, the third conductive layer, the fourth conductive layer, and the fifth conductive layer may be made of a metal material, such as, any one or more of silver (Ag), copper (Cu), aluminum (Al), and molybdenum (Mo), or an alloy material of the above metals, such as, an aluminum-neodymium alloy (AlNd), or a molybdenum-niobium alloy (MoNb), which may be in a single layer structure, or a multi-layer composite structure, such as, Mo/Cu/Mo, etc. The first insulation layer, the second insulation layer, the third insulation layer, the fourth insulation layer, and the fifth insulation layer may be made of any one or more of Silicon Oxide (SiOx), Silicon Nitride (SiNx), and Silicon OxyNitride (SiON), and may be in a single layer, a multi-layer, or a composite layer. The sixth insulation layer and the seventh insulation layer may be made of an organic material, such as polyimide, acrylic, or polyethylene terephthalate. The pixel definition layer may be made of an organic material, such as polyimide, acrylic, or polyethylene terephthalate. However, the present embodiment is not limited thereto.

A structure and a preparation process of the display substrate of the embodiment are merely illustrative. In some examples, a corresponding structure may be changed and a patterning process may be added or reduced according to actual needs. For example, a passivation layer made of an inorganic insulation material may be formed between the sixth insulation layer and the fourth conductive layer. As another example, a bottom metal shielding layer may be provided on a side of the first semiconductor layer close to the base substrate, and an orthographic projection of the bottom metal shielding layer on the base substrate may cover orthographic projections of channel regions of the active layers of the first type of transistors on the base substrate so as to ensure a performance of the first type of transistors.

The preparation process of this example may be implemented using an existing mature manufacturing equipment, and may be compatible well with an existing manufacturing process, simple in process implementation, easy to implement, high in production efficiency, low in production cost, and high in yield.

In the display substrate according to the present embodiment, the first capacitor 41a of the pixel circuit may be formed by overlapping the first electrode plate 411a with the second electrode plate 412a. The first electrode plate 411a may serve as a first electrode of the first capacitor 41a and is connected to the third transistor 33a, the first transistor 31a, and a second electrode of the second capacitor 41a. The second electrode plate 412a of the first capacitor 41a may serve as a second electrode of the first capacitor 41a to be electrically connected to the first power supply line. The first electrode plate 411a is located in the first conductive layer and serves as a lower electrode plate; and the second electrode plate 412a is located in the second conductive layer and serves as an upper electrode plate.

In the display substrate according to the present embodiment, the second capacitor 42a of the pixel circuit may be formed by overlapping the third electrode plate 421a with the fourth electrode plate 422a. The third electrode plate 421a may serve as a first electrode of the second capacitor 42a to be connected to the second transistor 32a; and the fourth electrode plate 422a may serve as a second electrode of the second capacitor 42a to be connected to the first electrode of the first capacitor 41a, the third transistor 33a, and the first transistor 31a. The fourth electrode plate 422a may be located in the fourth conductive layer and serves as a lower electrode plate; and the third electrode plate 421a may be located in the third conductive layer and serves as an upper electrode plate.

In the display substrate according to the present embodiment, the first electrode plate 411a of the first capacitor 41a of the pixel circuit simultaneously serves as a gate electrode of the third transistor 33a to be connected to the fourth electrode plate 422a of the second capacitor 42a through a via, and to be connected to the second electrode of the first transistor 31a through the fourth electrode plate 422a and the third connection electrode 503. The first electrode plate 411a may serve as a first node N1 in the pixel circuit. An orthographic projection of the third electrode plate 421a of the second capacitor 42a on the base substrate may cover an orthographic projection of the first electrode plate 411a on the base substrate. Since the first electrode plate 411a may serve as the first node N1 in the pixel circuit, and the third electrode plate 421a is used to cover and shield the first electrode plate 411a, so that an influence of other signals in the pixel circuit on the first node N1 may be effectively shielded, and the potential stability of the first node N1 may be guaranteed, thereby improving a display effect.

In the display substrate according to the present embodiment, second electrode plates of a plurality of first capacitors located in the second conductive layer may be of an integral structure connected to each other, forming lateral traces for transmitting a first voltage signal along the first direction X, and the first power supply line located in the fifth conductive layer may transmit a first voltage signal along the second direction Y. Since the first power supply line may be electrically connected to an integral structure of the ninth connection electrode located in the fourth conductive layer and the second electrode plate through a via, so that a mesh structure for transmitting the first voltage signal may be formed, which may not only effectively reduce a resistance of the first power supply line and reduce a voltage drop of the first voltage signal, but also effectively improve uniformity of the first power supply signal in the display substrate and effectively improve display uniformity, thereby improving display quality.

In the display substrate according to the present embodiment, the first power supply protrusion portion and the second power supply protrusion portion which are connected to the first power supply line to be of an integral structure are provided in the fifth conductive layer, so that a metal block with a large area may be formed; and moreover, the first electrode plate of the second capacitor included in the fifth conductive layer may also form a metal block with a large area, which may improve a flatness of a whole surface of the fifth conductive layer, and is beneficial to improving a flatness of the anode, thereby improving display uniformity.

In the display substrate according to the present embodiment, the first initial signal line may be located in the fourth conductive layer, and an orthographic projection of the first initial signal line on the base substrate may be at least partially overlapped with orthographic projections of the second auxiliary line located in the second conductive layer and the second scan line located in the third conductive layer on the base substrate, so as to form a stacked structure of traces of three conductive layers (including a second conductive layer, a third conductive layer and a fourth conductive layer), thereby saving more space of traces, which is beneficial to reducing the occupied space of the pixel circuit and achieving a display substrate with a high resolution.

In the display substrate according to the present embodiment, the second initial signal line may be located in the third conductive layer, and an orthographic projection of the second initial signal line on the base substrate may be at least partially overlapped with orthographic projections of the third initial signal line located in the second conductive layer and the compensation control line located in the first conductive layer on the base substrate, so that a stacked structure of traces of three conductive layers (including a first conductive layer, a second conductive layer and a third conductive layer) is formed, thereby saving more space of traces, which is beneficial to reducing the occupied space of the pixel circuit and achieving a display substrate with a high resolution.

In the display substrate according to the present embodiment, the pixel circuit may include two oxide thin film transistors (i.e., a first transistor and a second transistor), and the first transistor and the second transistor may be adjacent in the first direction and arranged in a staggered manner in the first direction X, so that more space of traces may be saved, which is beneficial to reducing the occupied space of the pixel circuit.

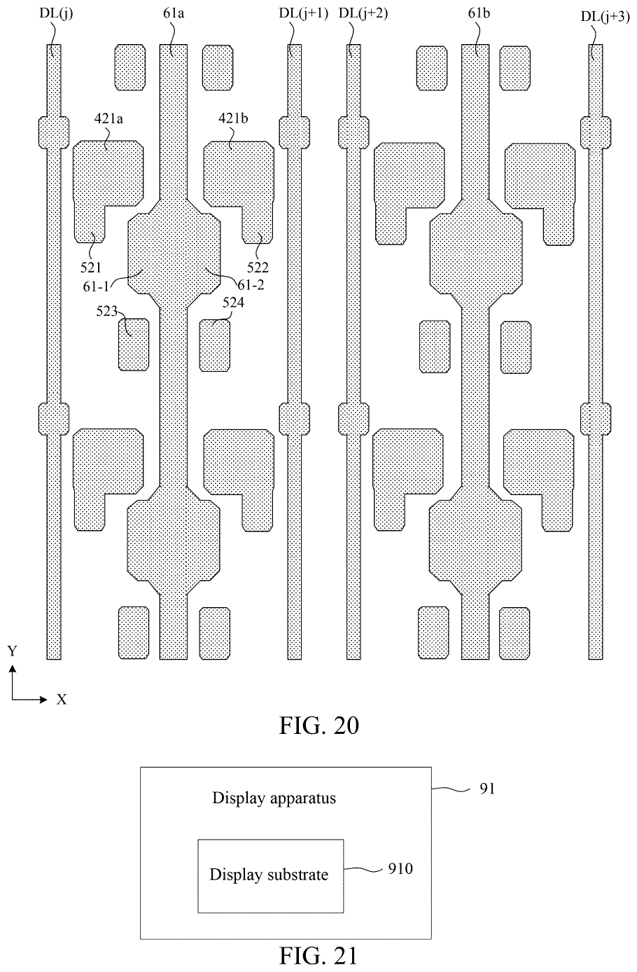

FIG. 21 is a schematic diagram of a display apparatus according to at least one embodiment of the present disclosure. In some examples, as shown in FIG. 21, the embodiment provides a display apparatus 91, including a display substrate 910 of the aforementioned embodiments. In some examples, the display substrate 91 may be a flexible OLED display substrate, a QLED display substrate, a Micro-LED display substrate, or a Mini-LED display substrate. The display apparatus may be a product having an image (including a still image or a moving image, herein the moving image may be a video) display function. For example, the display apparatus may be: displays, televisions, billboards, digital photo frames, laser printers with display function, telephones, mobile phones, picture screens, personal digital assistants (PDA), digital cameras, portable camcorders, viewfinders, navigators, vehicles, large-area walls, information inquiry equipment (such as business inquiry equipment in e-government, banks, hospitals, power departments, etc.), monitors, etc. As another example, the display apparatus may be any one of a micro-display, a VR device or an AR device including a micro-display.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict. It should be noted that the above examples or embodiments are exemplary only but not restrictive. Therefore, the present disclosure is not limited to what is specifically shown and described herein. Various modifications, substitutions or omissions may be made in forms and details of implementation modes without departing from the scope of the present disclosure.

1. A pixel circuit, comprising a driving sub-circuit, a first voltage writing sub-circuit, a second voltage writing sub-circuit, a writing control sub-circuit, a coupling sub-circuit, a first reset sub-circuit, and a storage sub-circuit; wherein
the driving sub-circuit is coupled to a first node, a second node and a third node, and is configured to provide a driving signal to the third node under control of the first node;
the first reset sub-circuit is coupled to the first node, a first reset control line and a first initial signal line, and is configured to write a first initial signal provided by the first initial signal line to the first node under control of the first reset control line;
the first voltage writing sub-circuit is coupled to the third node, a first scan line and a data line, and is configured to write a data signal provided by the data line to the third node under control of the first scan line in a data writing stage;
the second voltage writing sub-circuit is coupled to the second node, a compensation control line and a second initial signal line, and is configured to write a threshold voltage of the driving sub-circuit to the third node under control of the compensation control line in a threshold compensation stage;
the writing control sub-circuit is coupled to the third node, a fourth node and a second scan line, and is configured to conduct the third node and the fourth node under control of the second scan line in the data writing stage and the threshold compensation stage;
the coupling sub-circuit is coupled to the first node and the fourth node, and is configured to couple a signal written to the fourth node to the first node;
the storage sub-circuit is coupled to the first node and a first power supply line; and
in one display period, the threshold compensation stage is independent of the data writing stage.

2. The pixel circuit according to claim 1, wherein in one display period, the threshold compensation stage is before the data writing stage, and a time length of the threshold compensation stage is longer than a time length of the data writing stage.

3. The pixel circuit according to claim 1, further comprising a first control sub-circuit and a second control sub-circuit; wherein the first control sub-circuit is coupled to the second node, a first control line and the first power supply line, and is configured to conduct the first power supply line and the second node under control of the first control line; and
the second control sub-circuit is coupled to the third node, a second control line and a fifth node, and is configured to transmit the drive signal to the fifth node under control of the second control line; and the fifth node is coupled to a first electrode of a light emitting element, and a second electrode of the light emitting element is coupled to a second power supply line.

4. The pixel circuit according to claim 3, wherein a first control signal provided by the first control line is different from a second control signal provided by the second control line.

5. The pixel circuit according to claim 3, further comprising a third voltage writing sub-circuit, which is coupled to the third node, a third scan line, and a fourth initial signal line and configured to write a fourth initial signal provided by the fourth initial signal line to the third node under control of the third scan line before the threshold compensation stage.

6. The pixel circuit according to claim 5, wherein the first initial signal provided by the first initial signal line is the same as a second initial signal provided by the second initial signal line, and the fourth initial signal provided by the fourth initial signal line is greater than the first initial signal provided by the first initial signal line.

7. The pixel circuit according to claim 5, wherein a first control signal provided by the first control line is the same as a second control signal provided by the second control line.

8. The pixel circuit according to claim 3, further comprising a second reset sub-circuit, which is coupled to the fifth node, a second reset control line, and a third initial signal line and is configured to write a third initial signal provided by the third initial signal line to the fifth node under control of the second reset control line.

9. The pixel circuit according to claim 8, wherein the first reset sub-circuit comprises a first transistor; a gate electrode of the first transistor is coupled to the first reset control line, a first electrode of the first transistor is coupled to the first initial signal line, and a second electrode of the first transistor is coupled to the first node;
the writing control sub-circuit comprises a second transistor, wherein a gate electrode of the second transistor is coupled to the second scan line, a first electrode of the second transistor is coupled to the third node, and a second electrode of the second transistor is coupled to the fourth node;
the driving sub-circuit comprises a third transistor, wherein a gate electrode of the third transistor is coupled to the first node, a first electrode of the third transistor is coupled to the second node, and a second electrode of the third transistor is coupled to the third node;
the first voltage writing sub-circuit comprises a fourth transistor, wherein a gate electrode of the fourth transistor is coupled to the first scan line, a first electrode of the fourth transistor is coupled to the data line, and a second electrode of the fourth transistor is coupled to the third node;
the second voltage writing sub-circuit comprises a seventh transistor, wherein a gate electrode of the seventh transistor is coupled to the compensation control line, a first electrode of the seventh transistor is coupled to the second initial signal line, and a second electrode of the seventh transistor is coupled to the second node;
the first control sub-circuit comprises a fifth transistor, wherein a gate electrode of the fifth transistor is coupled to the first control line, a first electrode of the fifth transistor is coupled to the first power supply line, and a second electrode of the fifth transistor is coupled to the second node;
the second control sub-circuit comprises a sixth transistor, wherein a gate electrode of the sixth transistor is coupled to the second control line, a first electrode of the sixth transistor is coupled to the third node, and a second electrode of the sixth transistor is coupled to the fifth node;
the second reset sub-circuit comprises an eighth transistor, wherein a gate electrode of the eighth transistor is coupled to the second reset control line, a first electrode of the eighth transistor is coupled to the third initial signal line, and a second electrode of the eighth transistor is coupled to the fifth node;
wherein the third transistor, the fourth transistor, the fifth transistor, the sixth transistor, the seventh transistor, and the eighth transistor are a first type of transistors; the first transistor and the second transistor are a second type of transistors; and a transistor type of the first type of transistors and a transistor type of the second type of transistors are different.

10. (canceled)

11. The pixel circuit according to claim 1, wherein the storage sub-circuit comprises a first capacitor; the coupling sub-circuit comprises a second capacitor; a first electrode of the first capacitor is coupled to the first node, and a second electrode of the first capacitor is coupled to the first power supply line; and a first electrode of the second capacitor is coupled to the fourth node, and a second electrode of the second capacitor is coupled to the first node.

12. A method for driving a pixel circuit, applied to the pixel circuit according to claim 1, comprising:
writing, by a first reset sub-circuit, a first initial signal provided by a first initial signal line to a first node under control of a first reset control line;
in a threshold compensation stage, writing, by a second voltage writing sub-circuit, a threshold voltage of a driving sub-circuit to a third node under control of a compensation control line, and conducting, by a writing control circuit, the third node and a fourth node and writing the threshold voltage to the fourth node under control of a second scan line;
in a data writing stage, writing, by a first voltage writing sub-circuit, a data signal provided by a data line to the third node under control of a first scan line, writing, by the writing control circuit, the data signal to the fourth node, and coupling, by a coupling sub-circuit, the signal written to the fourth node to the first node; and
providing, by the driving sub-circuit, a driving signal to the third node under control of the first node.

13-16. (canceled)

17. A display substrate, comprising a base substrate, a circuit structure layer disposed on the base substrate, wherein the circuit structure layer comprises a plurality of pixel circuits, at least one of the plurality of pixel circuits comprises a first capacitor and a second capacitor; the second capacitor is located on a side of the first capacitor away from the base substrate, and an orthographic projection of the second capacitor on the base substrate is at least partially overlapped with an orthographic projection of the first capacitor on the base substrate;
the first capacitor comprises a first electrode plate and a second electrode plate; the second capacitor comprises a third electrode plate and a fourth electrode plate; the second electrode plate of the first capacitor is located on a side of the first electrode plate away from the base substrate, the third electrode plate of the second capacitor is located on a side of the fourth electrode plate away from the base substrate, and the fourth electrode plate of the second capacitor is located on a side of the second electrode plate of the first capacitor away from the base substrate; and the first electrode plate of the first capacitor is connected to the fourth electrode plate of the second capacitor.

18. The display substrate according to claim 17, wherein the second electrode plate of the first capacitor has a hollow region, and an orthographic projection of a connection position between the first electrode plate and the fourth electrode plate on the base substrate is located within a range of an orthographic projection of the hollow region on the base substrate,
wherein an orthographic projection of the third electrode plate of the second capacitor on the base substrate covers orthographic projections of the first electrode plate and the fourth electrode plate on the base substrate.

19. (canceled)

20. The display substrate according to claim 17, wherein second electrode plates of first capacitors of a plurality of pixel circuits arranged along a first direction are of an integral structure connected to each other, the integral structure is connected with a first power supply line extending along a second direction to form a mesh structure for transmitting a first voltage signal, and the first power supply line is located on a side of the integral structure away from the base substrate; and the first direction intersects with the second direction,
wherein the integral structure formed by connecting the second electrode plates of the first capacitors of the plurality of pixel circuits arranged along the first direction is connected to the first power supply line through a ninth connection electrode, and the ninth connection electrode is located on a side of the integral structure away from the base substrate and located on a side of the first power supply line close to the base substrate.

21. (canceled)

22. The display substrate according to claim 17, wherein the pixel circuit is connected to a first initial signal line, a second initial signal line, and a third initial signal line; and the first initial signal line, the second initial signal line, and the third initial signal line are located in different conductive layers.

23. The display substrate according to claim 17, wherein the pixel circuit comprises at least one first type of transistor and at least one second type of transistor;
in a direction perpendicular to the display substrate, the circuit structure layer comprises: a first semiconductor layer, a first conductive layer, a second conductive layer, a second semiconductor layer, a third conductive layer, a fourth conductive layer, and a fifth conductive layer which are disposed on the base substrate, wherein the first semiconductor layer comprises an active layer of the at least one first type of transistor, and the second semiconductor layer comprises an active layer of the at least one second type of transistor.

24. The display substrate according to claim 23, wherein the first electrode plate of the first capacitor is located in the first conductive layer, and the second electrode plate of the first capacitor is located in the second conductive layer; and the third electrode plate of the second capacitor is located in the fifth conductive layer, and the fourth electrode plate of the second capacitor is located in the fourth conductive layer.

25. The display substrate according to claim 23, wherein the pixel circuit is electrically connected to a first initial signal line which is located in the fourth conductive layer, and an orthographic projection of the first initial signal line on the base substrate is at least partially overlapped with orthographic projections of traces located in the second conductive layer and the third conductive layer on the base substrate.

26. The display substrate according to claim 23, wherein the pixel circuit is electrically connected to a second initial signal line and a third initial signal line, the third initial signal line is located in the second conductive layer, the second initial signal line is located in the third conductive layer, and an orthographic projection of the second initial signal line on the base substrate is at least partially overlapped with an orthographic projection of the third initial signal line on the base substrate,
wherein the pixel circuit comprises two second type of transistors, which are adjacent in a first direction and arranged in a staggered manner along the first direction.

27. (canceled)

28. The display substrate according to claim 17, wherein the plurality of pixel circuits are divided into a plurality of pixel circuit groups, each pixel circuit group comprises two pixel circuits disposed to be adjacent along the first direction, and the two pixel circuits in the pixel circuit group are disposed symmetrically with respect to a first centerline of the pixel circuit group in the first direction,
wherein the two pixel circuits in the pixel circuit group are connected to a same first power supply line, the first power supply line is located on the first centerline, and data lines to which the two pixel circuits are connected are located on two sides of the first power supply line in the first direction.

29-30. (canceled)
